(19) United States
(12) Patent Application Publication
(10) Pub. No.: US 2025/0271334 A1
(43) Pub. Date: Aug. 28, 2025

(54) APPARATUS AND METHODS FOR ULTRAMICROTOME SPECIMEN PREPARATION

(71) Applicant: UNIVERSITY OF KANSAS, Lawrence, KS (US)

(72) Inventor: Eduardo ROSA-MOLINAR, Lawrence, KS (US)

(21) Appl. No.: 18/858,554

(22) PCT Filed: Apr. 21, 2023
(86) PCT No.: PCT/US2023/019483

§ 371 Date: Oct. 21, 2024

Related U.S. Application Data
(60) Provisional application No. 63/333,538, filed on Apr. 21, 2022.

(51) Int. Cl. G01N 1/06

(52) U.S. Cl. CPC G01N 1/06

(57) ABSTRACT

A plurality of accessory components for use in respective reel to real sectioning, serial sectioning, and array tomography sectioning described herein incorporate mechanical and electro-mechanical engineering to provide accessory tools for attachment to and use with a microtome, as shown in several of the figures of this disclosure.

### CROSS REFERENCE TO RELATED APPLICATIONS

This application claims benefit of U.S. Application Ser. No. 63/333,538, filed on Apr. 21, 2022, which is hereby incorporated herein by reference in its entirety.

### BACKGROUND

Electron microscopy can be advantageously used to investigate the ultrastructure of biological samples such as cells and tissue, polymer resin samples, and crystalline samples such as inorganic substances. Two types of electron microscopes are known: scanning electron microscopes (hereinafter sometimes referred to as SEMs) and transmission electron microscopes (hereinafter sometimes referred to as TEMs).

In an electron microscope column, incident electrons are accelerated into, for example, epoxy resin-embedded samples. A number of interactions between the accelerated electrons and atoms contained within the resin-embedded sample result in elastic and inelastic scattering of electrons (known as the electron interaction volume). A number of signals generated (i.e., secondary electrons, backscattered electrons, cathodoluminescence, auger electrons, characteristic X-rays, and Bremsstrahlung X-rays) can be used for high-resolution electron microscopic imaging of ultrastructural features of cell and tissue organelles.

To advance different kinds of microscopy, researchers associated with this disclosure have developed a mechanically flexible and bendable conductive film that holds tissue, permits nanoscale cellular imaging, and eliminates charging artifacts resulting from the electron beam in scanning electron microscopes, transmission electron microscopes, etc. The conductive film can also be used for optical light microscopes to transmit light through the substrate for bright-field and fluorescence imaging.

In one embodiment of these films, graphene is uniformly coated on one side of a 0.5-mil Polyimide Kapton Film (No Additional Adhesive) 6.4 mm [¼ inch] wide×33 m [36 yd] long (PIT0.5N/6.4). Different electrical conductivity can be achieved by controlling the graphene coating's thickness, ranging from tens of nanometers to hundreds of nanometers. Typically, for about 5-10 nm thickness, a sheet resistance of less than 45 ohm/square is achieved.

The conductive fixation and graphene-based substrates make it possible to take advantage of inelastic scattering of electrons' capabilities to generate many signals (e.g., cathodoluminescence, Bremsstrahlung X-rays characteristic X-ray, secondary electrons, backscatter electrons, and Auger electrons) that scatter in an angular dependent manner. Additional research is exploiting their angle of deflection and their energy loss to gather chemical elemental information (e.g., C, N, Mg, P, Fe, Cu, and Zn) at the tissue, cellular, and subcellular levels. This enables mapping metal ions at electrical synapses on the nanometric-micrometric spatial scale, which is currently impossible to do.

Co-pending and commonly owned international PCT Application Serial No. PCT/US2019/013051, “Conductive Fixation of Organic Material,” filed Jan. 10, 2018, and U.S. Provisional Application Ser. No. 62/778,140 “Graphene Based Substrates for Imaging,” filed on Dec. 11, 2018, discuss the graphene substrates in more detail, and are incorporated herein as if set forth in their entireties.

To take advantage of high-resolution microscopies, the life sciences need better sample preparation workflows, reagents that will overcome charging and sample damage caused by electron beam-sample interactions in the electron microscope, and tools for accurate microscopic imaging in both two dimensional and three-dimensional views. These tools are set forth in detail herein.

### BRIEF SUMMARY OF THE DISCLOSURE

Advancements in the kinds of slide mechanisms, or sample substrates, for sample collection have led to a need for more advanced sample collection on better slide surfaces than traditional slides that are known in the art. This disclosure provides a plurality of accessory tools for attachment to and use with an ultramicrotome, particularly for automatically collecting the sample sections onto a specialized sample surface, including but not limited to a graphene-based surface that is configured for accurate imaging under numerous kinds of microscopes and imagers. As an overview, this disclosure presents accessory tools for a microtome that aid in volume electron microscopy and specimen preparation. This disclosure provides supporting disclosure for at least four (4) different holders for four (4) different volume resin-based electron microcopy techniques (e.g., serial section scanning transmission electron microscopy (ssSTEM; see FIGS. 27A, 27B); array tomography (Arraytome [AT]; see FIG. 31] and reel-to-reel microscopy [rrM; see FIG. 8]). In one non-limiting embodiment, each of these configurations (ssSTEM, AT, rrM) are disclosed herein with the appropriate accessory tools that accommodate the microtome depositing ultra-thin (50 nm or less) and/or semi-thin (above 50 nm) sections on the Kapton graphene coated tape, coverslips, stubs, and grids. These sample collection surfaces can be post-stained or immuno-stained using fluorescence and/or chromogens of immunogold and/or immunogold derivative labels.

As part of these integrated systems, described herein are improved knife stage adaptors that reduce or eliminate vibration of the knife stage adaptor (and attached accessories) during ultramicrotome operation. The knife stage adaptor can interface with any commercial ultramicrotome such as, e.g., but not limited to, Sorvall (MT 2; MT 2B; MT 5000; MT 6000); Leica (UC6; UC7); RMC Boeckeler (PowerTome) ultramicrotomes. By reducing or eliminating vibration, the quality of sample preparation (e.g., using the range of accessories for sample sectioning and collection operations that accommodate reel-to-reel sectioning, serial sectioning, and array tomography sectioning, and that can be interfaced with the knife stage adaptor) can be dramatically improved.

In some aspects, the knife stage adapter can comprise a base portion adapted to couple with an upper region of a ultramicrotome knife-stage; an elastomeric bushing (e.g., a rubber bushing) disposed between the base portion and the upper region of the ultramicrotome knife-stage, wherein the elastomeric bushing vibrationally isolates the base portion from the ultramicrotome; a platform region receiving at least one adjustment screw attaching the platform region to the base portion at a plurality of selectable heights; and an adapter edge configured to receive a plurality of specimen substrate holders in a modular connection. Examples of substrate holders can comprise, for example, a reel-to-reel frame, a coverslip vise, a triggered holding apparatus, and/or a multigrid holder.

In some aspects, the knife stage adapter can further comprise a lever arm configured for arcuate movement relative to the base portion and configured to adjust a position of the specimen substrate holder along the Z-axis.

In some examples, the base portion is fastened to the upper region of the ultramicrotome knife-stage via one or more set screws or bolts.

Also provided herein are multigrid holders that can be used to facilitate the user's transfer and placement of sectioned samples at target regions on one or more substrates (e.g., grids) during sectioning operations performed on the ultramicrotome.

In some aspects, the multigrid holders can comprise a body portion extending from a proximal region to a distal region; a mounting bracket coupled to the body portion; a distal mounting plate disposed beneath an engageable substrate cover; and a lever extending from the proximal region towards and operatively coupled to the engageable substrate cover, such that actuation of the lever shifts the engageable substrate cover from a first position where the engageable substrate cover is in intimate contact with the distal mounting plate to a second position where the engageable substrate cover is raised above the distal mounting plate. The engageable substrate cover can comprise one or more apertures that define regions of the distal mounting plate that are exposed when the engageable substrate cover is in the first position.

In some aspects, the mounting bracket can be adapted to engage and couple to a knife stage adapter described herein. In certain aspects, the mounting bracket can be adapted to engage and couple to the lever arm of a knife stage adapter described herein.

In some aspects, the mounting bracket can further comprise a fastener, such as a set screw or bolt, adapted to secure the mounting bracket to the knife stage adapter.

In some aspects, advancement of the lever towards the proximal region shifts the engageable substrate cover from the first position to the second position.

In some aspects, the multigrid holders can further comprise one or more sample substrates disposed on the distal mounting plate and secured beneath the engageable substrate cover, wherein the one or more apertures define regions of the sample substrates that are exposed for sample deposition.

In some aspects, the distal mounting plate can comprise one or more recesses formed within the distal mounting plate, each sized to receive a sample substrate. In certain aspects, when the engageable substrate cover is in the first position, the one or more recesses are registered with the one or more apertures in the engageable substrate cover, such that a sample substrate present in the one or more recesses are exposed for sample deposition.

In some aspects, the one or more recesses are sized to accept an electron microscopy grid. For example, in certain aspects, the one or more recesses are about 3.05 mm in diameter, and wherein the one or more apertures are smaller than 3.05 mm in diameter so as to secure an electron microscopy grid beneath the engageable substrate cover when the engageable substrate cover is in the first position.

### BRIEF DESCRIPTION OF THE DRAWINGS

These and other features, aspects, and advantages of the present invention will become apparent from the following description and the accompanying exemplary implementations shown in the drawings, which are briefly described below.

FIG. 1 is a side view of an example ultramicrotome sample preparation device positioned proximately to a knife stage according to the background of this disclosure.

FIG. 2 is a side perspective view of an ultramicrotome positioned proximately a knife stage to receive cut samples onto a reel-to-reel tape according to embodiments of this disclosure.

FIG. 3A is a side perspective view of a knife stage adapter as set forth according to embodiments of this disclosure.

FIG. 3B is a side view of a reel-to-reel assembly for collecting cut resin samples from an ultramicrotome positioned proximately to a knife stage according to this disclosure.

FIG. 3C is a side view of a reel-to-reel assembly for collected cut resin samples from an ultramicrotome positioned proximately to a knife stage according to this disclosure.

FIG. 4 is a disassembled view of a modular reel-to-reel assembly for collecting cut resin samples from an ultramicrotome positioned proximately to a knife stage according to this disclosure.

FIG. 5 is a side view of a modular reel-to-reel assembly connected to a knife stage adapter and configured for attaching to a knife stage proximate an ultramicrotome for collecting cut resin samples from the ultramicrotome positioned proximately to the knife stage according to this disclosure.

FIG. 6 is a rear perspective view of a modular reel-to-reel assembly for collecting cut resin samples from an ultramicrotome positioned proximately to a knife stage according to this disclosure.

FIG. 7 is a rear perspective view of a modular reel-to-reel assembly for collecting cut resin samples from an ultramicrotome positioned proximately to a knife stage according to this disclosure.

FIG. 8 is a side perspective view of a modular reel-to-reel assembly for collecting cut resin samples from an ultramicrotome positioned proximately to a knife stage according to this disclosure.

FIG. 9 is a top perspective view of a modular reel-to-reel assembly for collecting cut resin samples from an ultramicrotome positioned proximately to a knife stage according to this disclosure.

FIG. 10 is a rear perspective view of a modular reel-to-reel assembly for collecting cut resin samples from an ultramicrotome positioned proximately to a knife stage according to this disclosure.

FIG. 11 is a top side perspective view of a modular reel-to-reel assembly for collecting cut resin samples from an ultramicrotome positioned proximately to a knife stage according to this disclosure.

FIG. 12A is a side plan view of a modular reel-to-reel assembly for collecting cut resin samples from an ultramicrotome positioned proximately to a knife stage according to this disclosure.

FIG. 12B is a side plan view of a knife stage and associated flanges and connectors for use with an ultramicrotome according to this disclosure.

FIG. 12C is a side plan view of a knife stage and associated flanges and connectors supporting a knife stage adapter connecting a reel-to-reel assembly in functional proximity to an ultramicrotome according to this disclosure.

FIG. 12D is a rear plan view of a knife stage configured for use with a knife stage adapter according to embodiments of this disclosure.

FIG. 13 is a top perspective view of a reel-to-reel frame positioning a tape used to collect cut samples from an ultramicrotome according to the embodiments of this disclosure.

FIG. 14 is a side perspective view of a reel-to-reel frame positioning a tape used to collect cut samples from an ultramicrotome according to the embodiments of this disclosure.

FIG. 15 is a side perspective view of a reel-to-reel frame positioning a tape used to collect cut samples from an ultramicrotome according to the embodiments of this disclosure.

FIG. 16 is a close-in side perspective view of a nose or snorkel of a reel-to-reel frame positioning a tape in proximity to an ultramicrotome to receive cut samples on the tape according to the disclosure herein.

FIG. 17 is a close-in top perspective view of a nose or snorkel of a reel-to-reel frame positioning a tape in proximity to an ultramicrotome to receive cut samples on the tape according to the disclosure herein.

FIG. 18 is a close-in top perspective view of a nose or snorkel of a reel-to-reel frame positioning a tape in proximity to an ultramicrotome to receive cut samples on the tape via a knife boat according to the disclosure herein.

FIG. 19 is a rear top perspective view of reel motors connected to a reel-to-reel frame according to embodiments of this disclosure.

FIG. 20A is a side top perspective view of reel motors connected to a reel-to-reel frame connected to a knife stage adapter connected to a knife stage of an ultramicrotome according to embodiments of this disclosure.

FIG. 20B is a side plan view of reel motors connected to a reel-to-reel frame connected to a knife stage adapter connected to a knife stage of an ultramicrotome according to embodiments of this disclosure.

FIG. 21 is a rear perspective view of a feeder reel and a take up reel assembly on a reel-to-reel frame connected to a knife stage according to embodiments of this disclosure.

FIG. 22 is a top perspective view of a knife stage and associated cartesian positioning control features for positioning a knife boat relative to an ultramicrotome according to embodiments of this disclosure.

FIG. 23 is a rear perspective view of a reel-to-reel frame connected to a knife stage adapter with associated cartesian positioning control features for positioning a knife boat relative to an ultramicrotome according to embodiments of this disclosure.

FIG. 24 is a top perspective view of a knife stage and associated cartesian positioning control features configured for modular removal relative to an ultramicrotome according to embodiments of this disclosure.

FIG. 25 is a top perspective view of a knife stage and associated cartesian positioning control features configured for modular removal relative to an ultramicrotome according to embodiments of this disclosure.

FIG. 26 is a top perspective view of a reel-to-reel frame supporting a tape guide proximate a knife boat of a knife stage according to aspects of this disclosure.

FIG. 27A is a top perspective view of a trigger holder for a specimen that is adapted to connect to a knife stage adapter that connects to a knife stage of an ultramicrotome according to this disclosure.

FIG. 27B is a top perspective view of a trigger holder for a specimen that is adapted to connect to a knife stage adapter that connects to a knife stage of an ultramicrotome according to this disclosure.

FIG. 28 is a side perspective view of a modular reel-to-reel frame that has been disconnected from a knife stage adapter and configured for storage on a stand according to embodiments herein.

FIG. 29 is a side perspective view of a knife stage adapter configured for receiving specimen holders according to the embodiments herein.

FIG. 30 is a top perspective view of a central specimen holder in the form of a vise that clips a substrate that receives a cut specimen from a knife edge proximate an ultramicrotome according to this disclosure.

FIG. 31 is a top perspective view of a central specimen holder in the form of a vise that clips a substrate that receives a cut specimen from a knife edge proximate an ultramicrotome according to this disclosure.

FIG. 32A is a top perspective view of a central specimen holder in the form of a vise that clips a substrate that receives a cut specimen from a knife edge proximate an ultramicrotome according to this disclosure.

FIG. 32B is a side perspective view of a central specimen holder in the form of a vise that clips a substrate that receives a cut specimen from a knife edge proximate an ultramicrotome according to this disclosure.

FIG. 33 is a schematic view of an example computer environment in which all electronic controls of this disclosure may use with appropriate modification according to the embodiments herein.

FIG. 34 is a side perspective view of an example multigrid holder.

FIG. 35 is a top view of an example multigrid holder.

FIG. 36 is a perspective view of an example multigrid holder attached to a knife stage adapter.

FIG. 37 is a perspective view illustrating how the orientation of the mounted multigrid holder can be adjusted using the lever arm of the knife stage adaptor so as to position the multigrid holder to facilitate the user's transfer and placement of sectioned samples at target regions on one or more sample substrates during sectioning operations performed on the ultramicrotome (e.g., in contact with or proximity to the knife boat).

### DETAILED DESCRIPTION

This disclosure describes an economical, compact device and system developed under the acronym “STAR”, which stands for “Scanning Transmission, Arraytome, Reel-to-Reel Microscopy.” Generally, this is a microscopy system that accommodates sample preparation with a commercial microtome and numerous specialized attachment accessories and tools that adapt the microtome for more efficient sample delivery. In one embodiment, STAR is a versatile, all-in-one ultramicrotome knife stage component accessory tool that is adaptable to any commercial ultramicrotome such as, e.g., but not limited to, Sorvall (MT 2; MT 2B; MT 5000; MT 6000); Leica (UC6; UC7); RMC Boeckeler (PowerTome) ultramicrotomes. The tools described herein accommodate the collection of hundreds to thousands of ultra-thin (thickness of 50 nm or less) and/or semi-thin (thickness above 50 nm), semi-thick (thickness between 51 nm and 100 nm) and thick (thickness between 101 nm and 200 nm) sample sections that can be automatically and continuously collected from a diamond knife edge onto a graphene-based, or other specialized material, surface. In some non-limiting embodiments, the sample collection surfaces may include coated 0.5-mil Polyimide [Kapton] Film No Adhesive 6.4 mm [¼″] wide×33 m [36 yd] long (PIT0.5N/6.4) tape for reel-to-reel microscopy, graphene coated coverslips, and graphene coated grids that collect samples cut from the microtome machinery. The references to graphene surfaces described herein are for example only and not limiting of the tools or uses of the tools described herein.

As part of this integrated system, described herein are improved knife stage adaptors that reduce or eliminate vibration of the knife stage adaptor (and attached accessories) during ultramicrotome operation. The knife stage adaptor can interface with any commercial ultramicrotome such as, e.g., but not limited to, Sorvall (MT 2; MT 2B; MT 5000; MT 6000); Leica (UC6; UC7); RMC Boeckeler (PowerTome) ultramicrotomes. By reducing or eliminating vibration, the quality of sample preparation (e.g., using the range of accessories for sample sectioning and collection operations that accommodate reel-to-reel sectioning, serial sectioning, and array tomography sectioning, and that can be interfaced with the knife stage adaptor) can be dramatically improved.

Also provided is a multigrid holder that can be interfaced with the knife stage adaptor.

The multigrid holder can facilitate the user's transfer and placement of sectioned samples at target regions on one or more substrates (e.g., grids) during sectioning operations performed on the ultramicrotome.

Co-pending and commonly owned international PCT Application Serial No. PCT/US2019/013051, “Conductive Fixation of Organic Material,” filed Jan. 10, 2018, and U.S. Provisional Application Ser. No. 62/778,140 “Graphene Based Substrates for Imaging,” filed on Dec. 11, 2018, discuss the graphene substrates in more detail, and are incorporated herein by reference as if set forth in their entireties. Co-pending and commonly owned International PCT Application Serial No. PCT/US2020/045239, “Electron Microscope Imaging Adaptor,” filed Aug. 6, 2020, and International PCT Application

Serial No. PCT/US2020/045233, “Apparatus and Methods for Ultramicrotome Specimen Preparation, filed Aug. 8, 2020, and international PCT Application Serial No. PCT/US2021/044741, “Coater for the Preparation of Carbon-Based Tape Substrates for Use in Imaging Applications,” filed Aug. 5, 2021, discuss component, systems, and methods for use in conjunction with the devices and systems described herein, and are incorporated herein by reference as if set forth in their entireties.

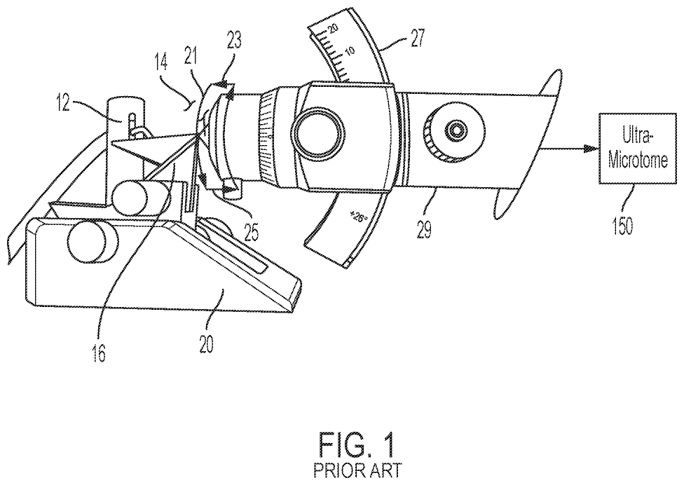

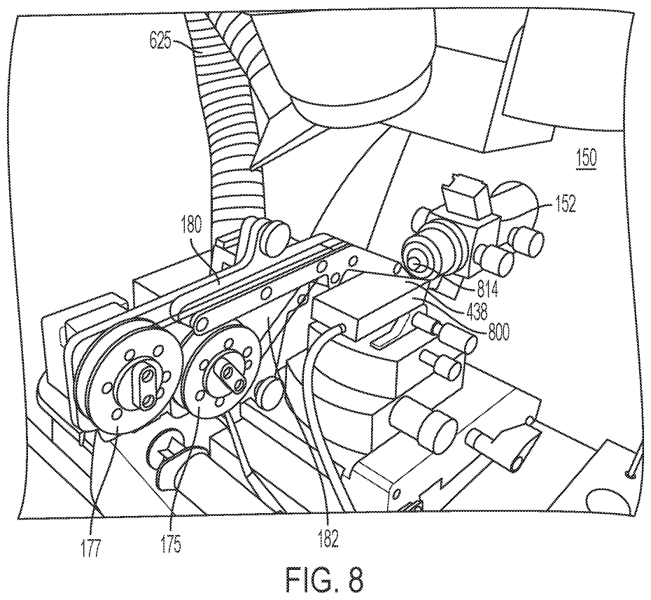

By way of overview, this disclosure includes reference to one non-limiting commercial embodiment of an ultramicrotome illustrated in PRIOR ART FIG. 1. As shown therein, an ultramicrotome is a sophisticated sampling and sectioning machine that holds a sample (not shown in the figures, but may include samples of biological tissue, tissue in paraffin blocks, cells and/or tissue in resin blocks, as well as samples of inanimate objects made of numerous materials to be analyzed). In a commonly available microtome 150, the tissue samples or sample blocks are held in a microtome sample attachment feature, such as the one illustrated in FIG. 8, Ref. 814, and that sample attachment feature, or nib 814, is an interchangeable part of an adjustable and continuously operated ultramicrotome arm 29. The ultramicrotome arm 152 may be configured to move up and down, pivoting along an arc shaped groove or range of motion 27, to continuously shave microscopically thin sample layers (or larger slices if desired) for placement onto a slide or substrate for analysis under various microscopy tools. An ultramicrotome 150, therefore, has associated computerized components that control power, mechanical movement, and general operation of the microtome system. Ultramicrotomes, therefore, accommodate the collection of hundreds to thousands of ultra-thin (thickness of 50 nm or less) and/or semi-thin (thickness above 50 nm) sample sections or sample layers that can be automatically and continuously collected from a diamond knife edge onto a graphene-based, or other specialized material, surface serving as a collection slide. These computer components are accessible for user control via an ultramicrotome controller as described herein.

Options in the ultramicrotome, such as the example prior art of FIG. 1, allow the user to place appropriate knife assemblies onto a knife stage. For example, and without limiting this disclosure, setting up an ultramicrotome 150 as shown in FIG. 1 includes positioning a knife boat 16 onto a knife carrier 20. The arcuately pivoting sample arm 29 moves in necessary dimensions 21 (up/down/arcuate), 23 (outward), 25 (inward) to continuously force a sample, or specimen block, against a knife blade 14 to shave off layers of ultra-thin and semi-thin sample sections of the overall sample held in the microtome sample attachment feature, or nib 814. The ultramicrotome has computer programmed memory to move the arm in all dimensions to cut sample sections against a knife blade 14. Prior embodiments of microtomes require retrieving the samples from cooling water held in the open chamber of the knife boat 16 and then further require placement of the sample sections on a slide for viewing under a microscope. In some embodiments, the surface of the distilled-deionized-filtered water contained in the knife boat 16 is maintained at the constant level during the sectioning process by a programmable Aladdin Single-Syringe infusion pump 12 (e.g., 60 mL plastic syringe) thus, ensuring proper ultrathin (thickness of 50 nm or less) and/or semi-thin (thickness above 50 nm) sectioning at the edge of the diamond knife. In some embodiments, the knife boat has a triangular shaped bottom forming the reservoir for water or other liquids.

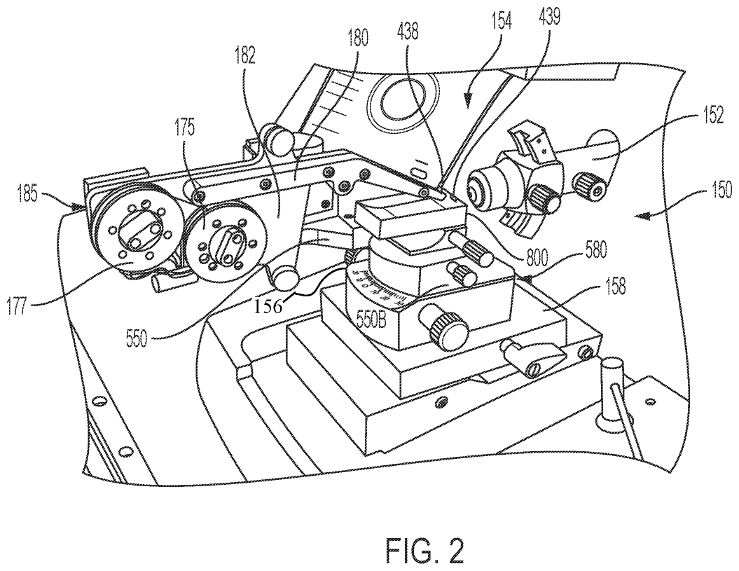

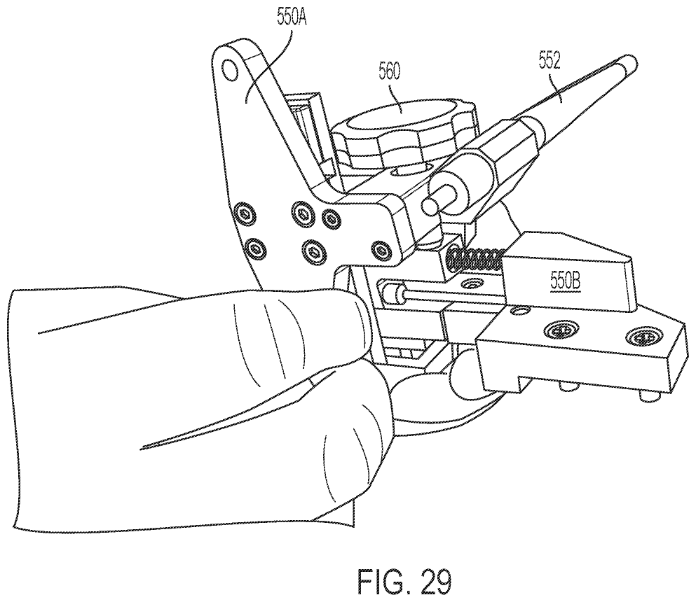

Development of modern accessories to ultramicrotomes, as shown in one embodiment of this disclosure, includes a knife stage adapter that allows numerous accessories, systems and methods of specimen collection to be used with multiple versions of ultramicrotomes 150. The knife stage adapter 550, therefore, may be seen as one kind of adapter that connects specimen collection systems described herein to an ultramicrotome knife carrier 20 or general knife stage 158. A knife stage adapter 550 is shown in FIGS. 2, 3A, 3B, 3C, and 29 and includes a base portion 550B adapted to connect to the knife stage 158 on an ultramicrotome 150. A platform region 550C receives at least one adjustment screw 560 attaching the platform region to the base portion 550B at a plurality of selectable heights. An adapter edge 550A is configured to receive a plurality of specimen substrate holders in a modular connection as discussed herein. The knife stage adaptor can further comprise an elastomeric bushing (580, e.g., a rubber bushing) disposed between the base portion (550B) and the upper region of an ultramicrotome knife-stage (158), wherein the elastomeric bushing vibrationally isolates the base portion from the ultramicrotome. In some cases, the bushing can reduce or eliminate vibration of the knife stage adaptor (and attached accessories) during ultramicrotome operation, improving sample sectioning and collection activities.

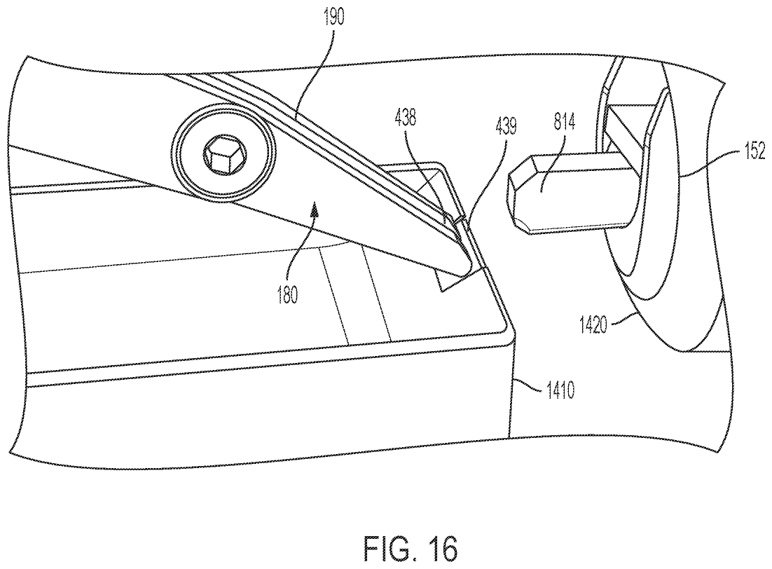

The knife stage adapter 550 can be configured to hold a number of different specimen holders, including but not limited to, at least a reel-to-reel frame 182, a trigger holder 300 (i.e., a scanning electron microscope stub holder), a coverslip vise 435, a multigrid holder (900), and other mechanical devices that can be positioned proximately to an ultramicrotome arm 152, a knife edge (e.g., a diamond knife edge) 439, and a knife boat 800. In some non-limiting embodiments, the diamond knife edge 439 may be connected to the knife boat at a 35 degree to 45 degree angle and may be approximately 2 mm to 8 mm wide. The knife stage adapter places these different specimen holders in positions to receive specimen slices onto a slide, a coverslip, or other specimen substrates (including a coated Kapton® polyimide specimen tape) that receives the specimens as slices or cut resin sections from a specimen attachment feature (e.g., nib 814 of FIG. 16) via the knife edge 439. The knife stage adapter 550 may include a lever arm 552 configured for arcuate movement relative to the base portion 550B and configured to adjust a position of the central specimen substrate holder along the Z-axis as shown in FIG. 2B.

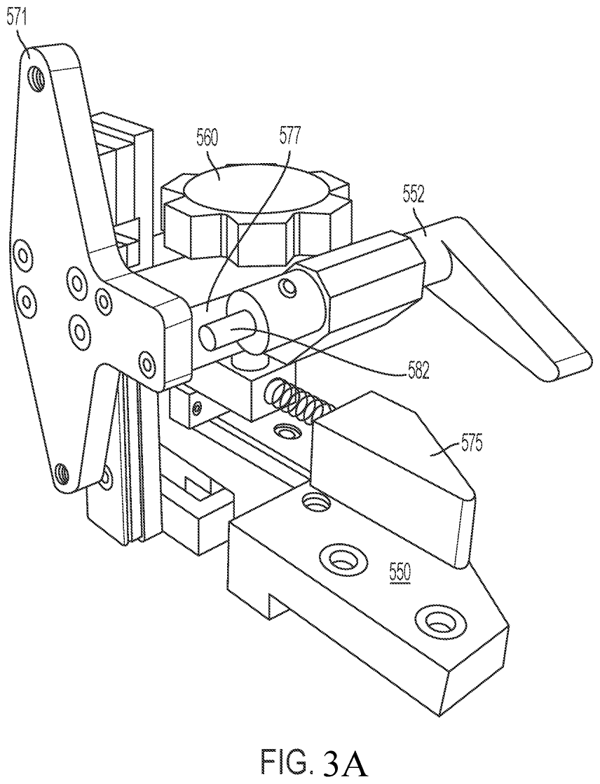

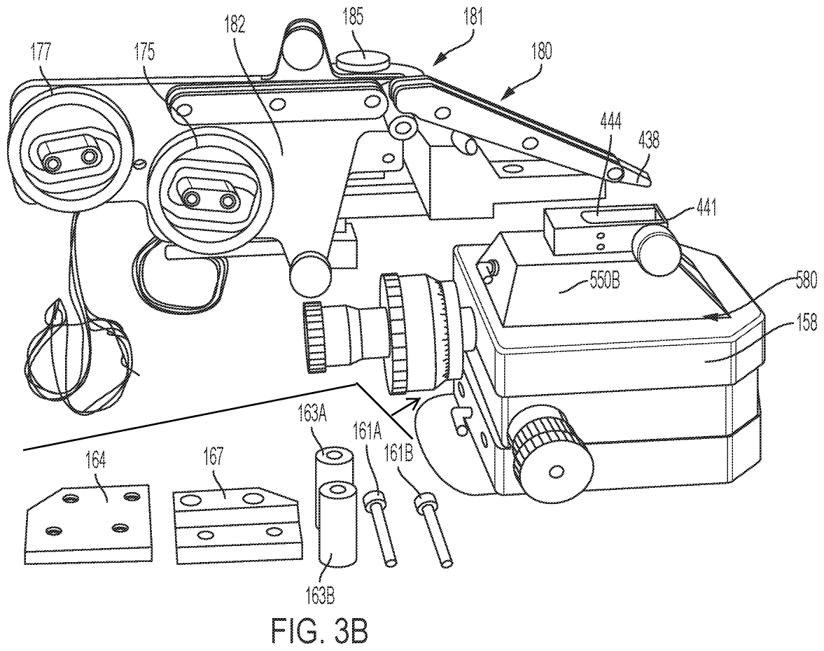

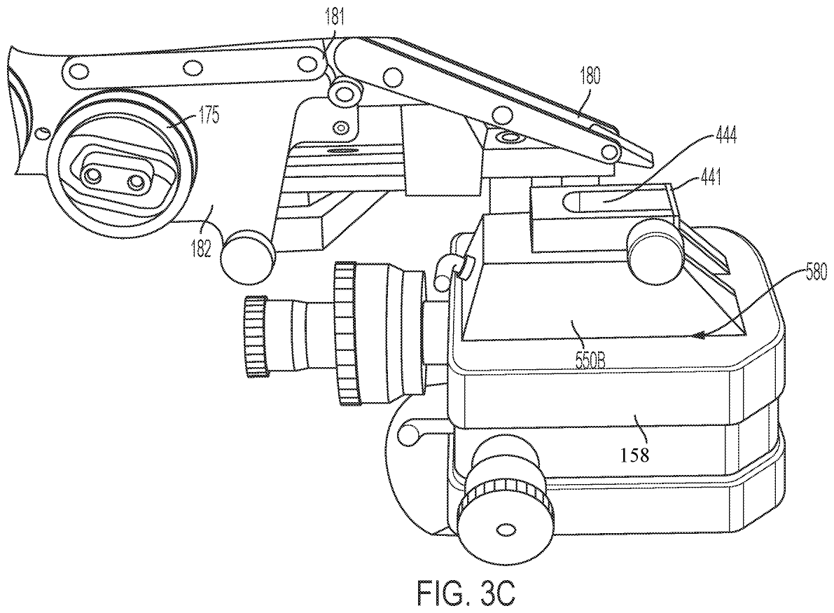

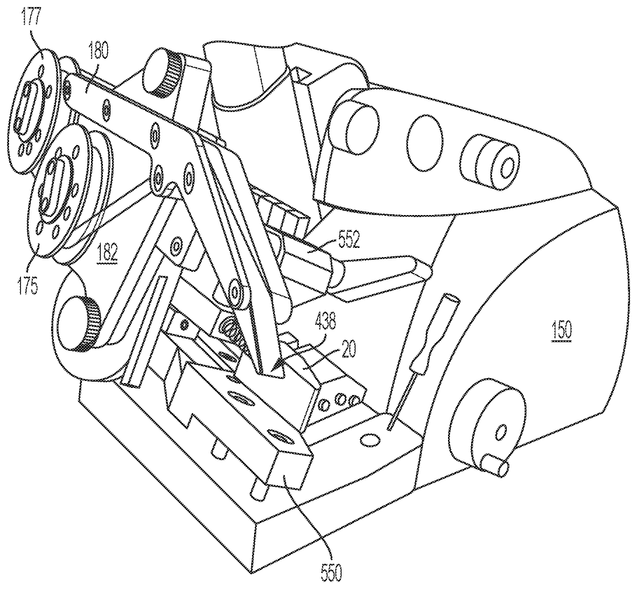

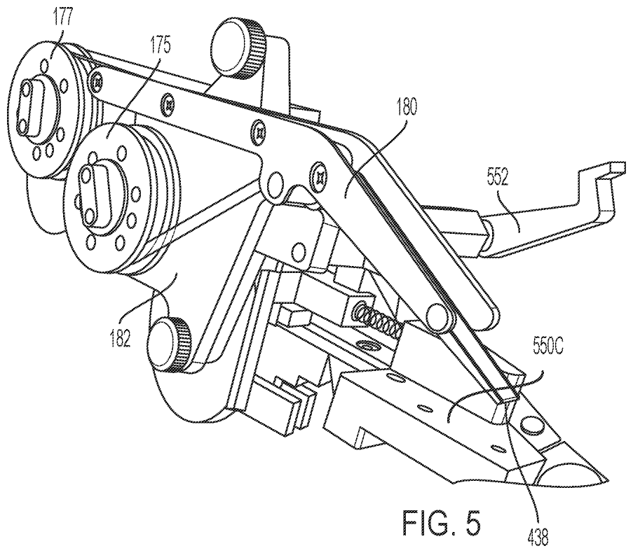

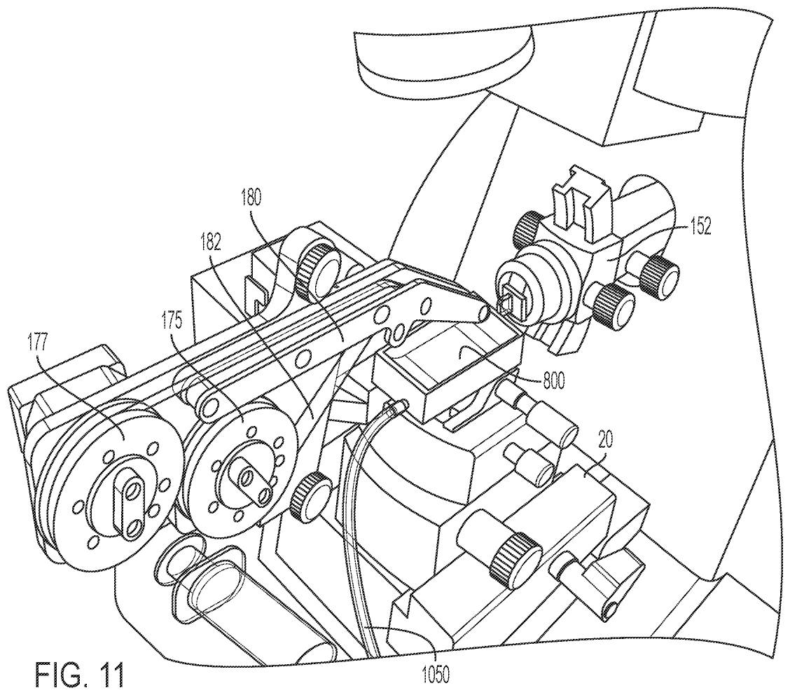

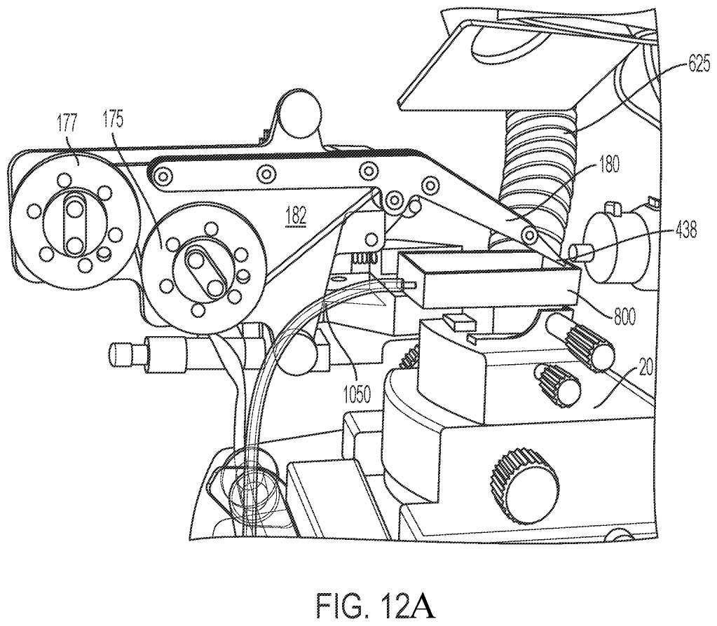

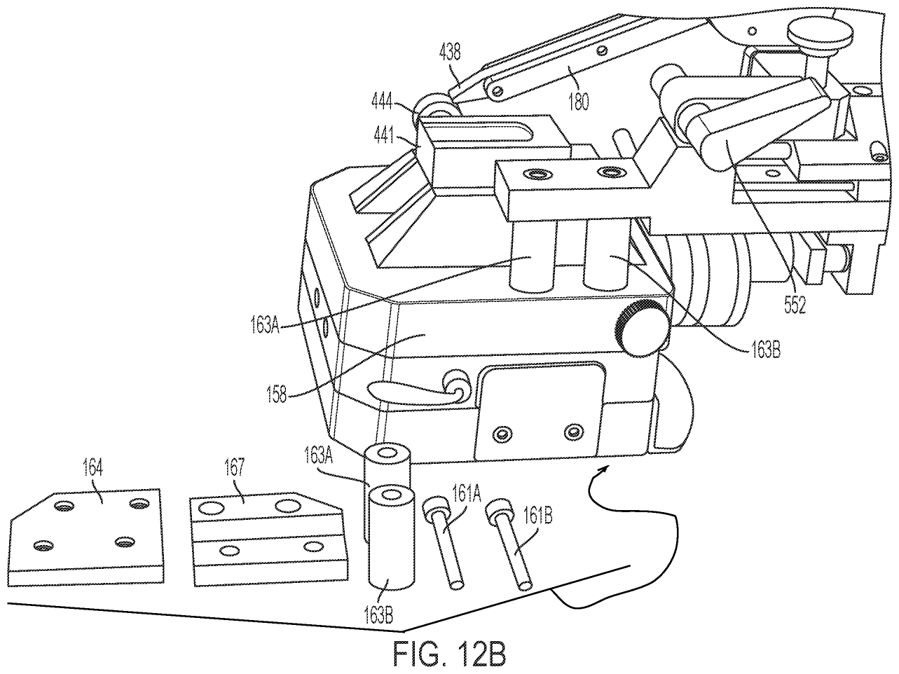

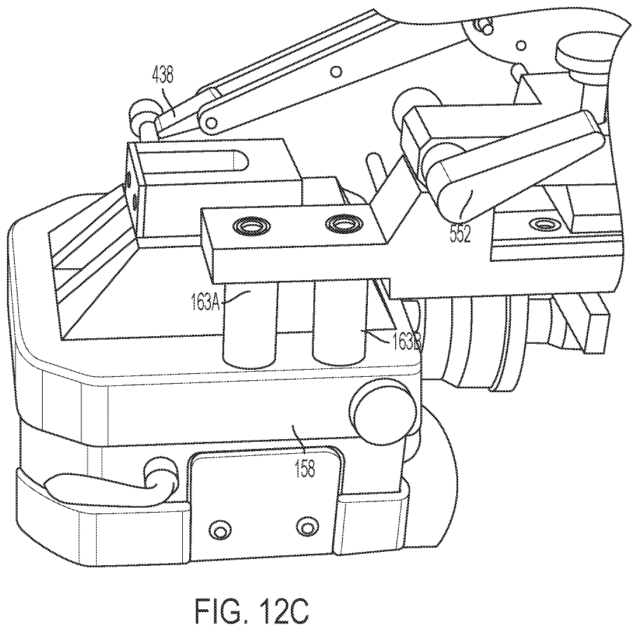

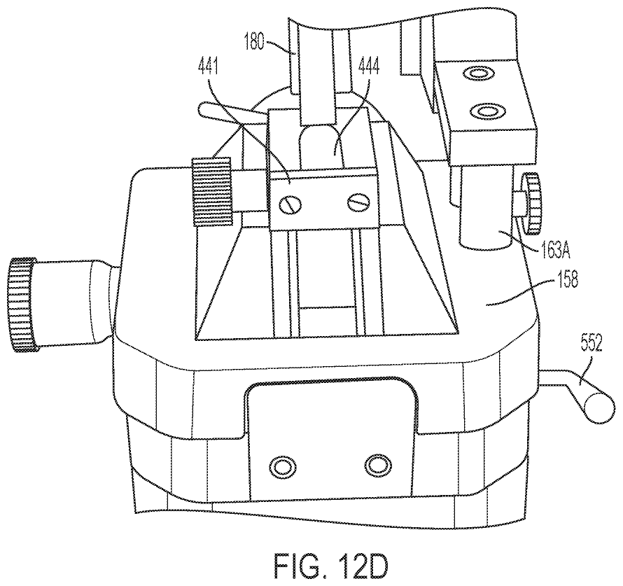

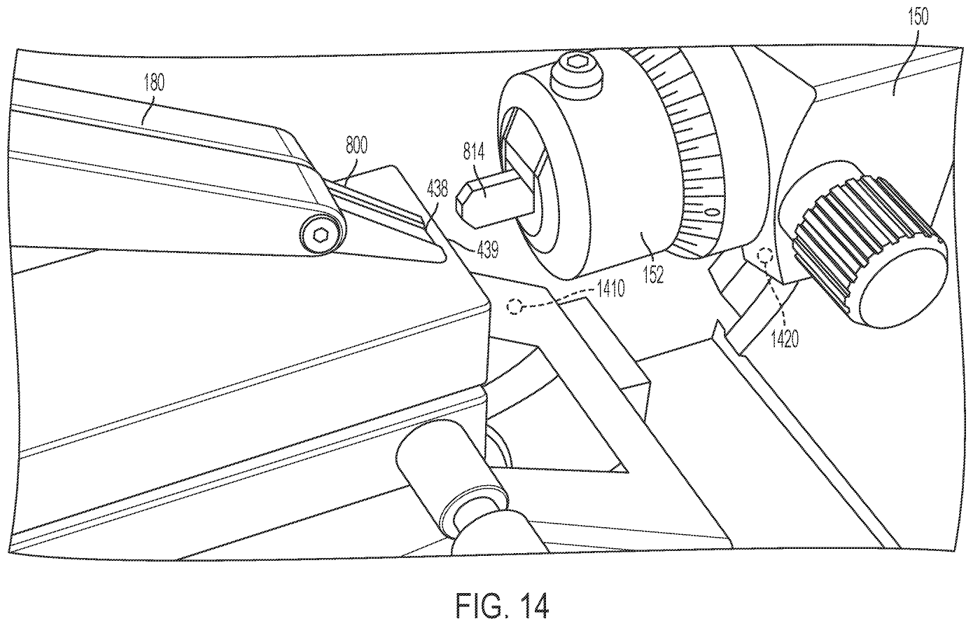

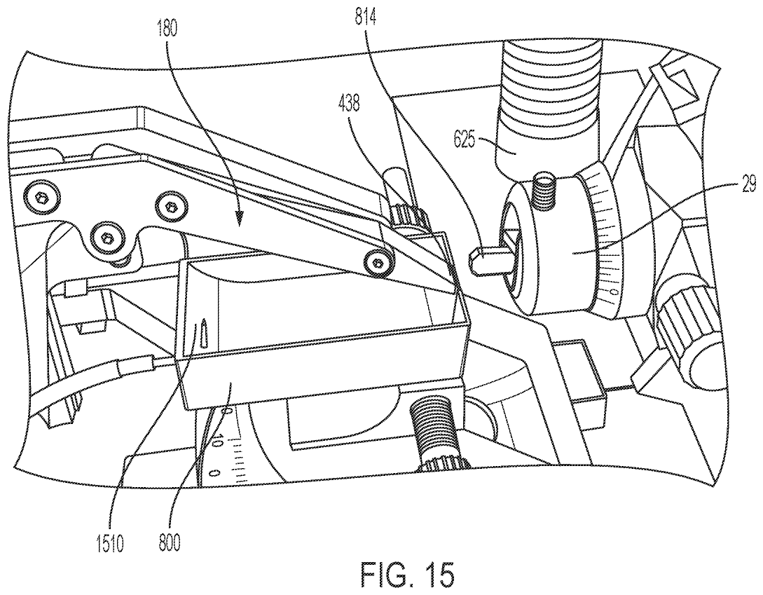

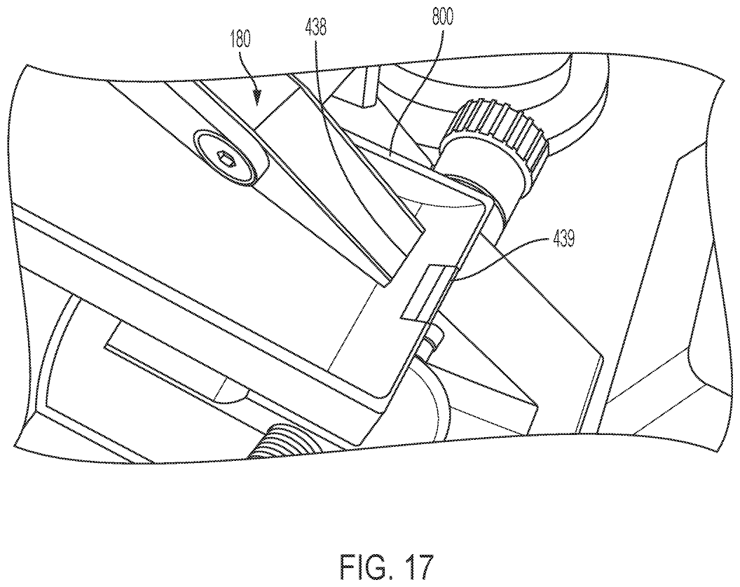

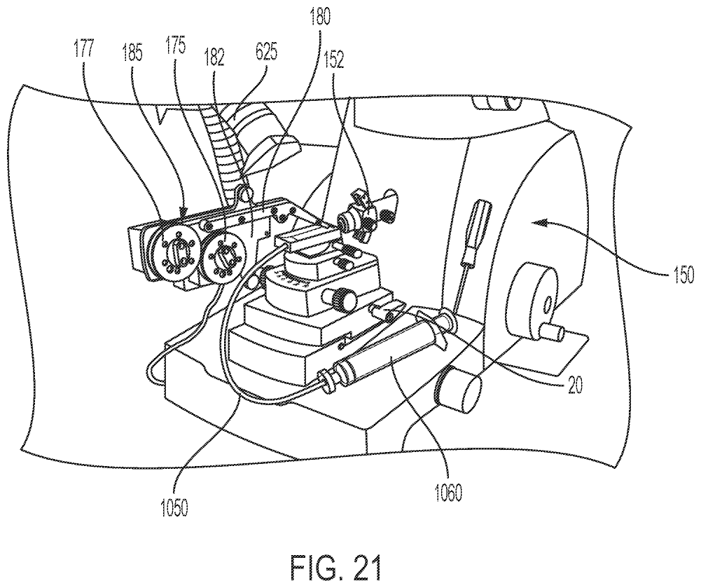

In one non-limiting embodiment, the above described knife stage adapter 550 can hold (and release) a reel-to-reel frame 182 for specimen tape-based electron microscopy. The reel-to-reel frame is shown in detail in FIGS. 3A-21, particularly FIGS. 4, 5, 8, 11 in conjunction with the knife stage adapter 550 attaching the reel-to-reel frame to a knife stage 158 of an ultramicrotome 150. The ultramicrotome may be any commercially available ultramicrotome, and the reel-to-reel frame bolts into the knife stage adaptor, which in turn bolts into the knife stage. In particular, the knife stage adapter bolts into an upper section of the knife stage. The knife stage 158 may be machined for precise dimensions in suitable materials such as aluminum, carbon, copper, chromium, brass, iron, molybdenum, nickel, stainless steel, titanium alloys; typically these materials are susceptible to extremely precise machining. As 3D printing moves forward, other polymers may present equally accurate fabrication opportunities. In one embodiment, the machined knife stage of FIGS. 3B and 3C is modularly attached to a knife carrier 441 defining a receptacle 444 for holding a knife boat 800 in place as described herein. FIG. 3B illustrates the flanges 164, 167 and support pillars 163A, 163B holding the knife stage adaptor 185 to the knife stage 158, as illustrated in FIGS. 12A-12D.

In one non-limiting embodiment of the reel-to-reel frame 182 shown in FIGS. 3A-3C, a feeder reel 175 is adapted to receive a length of a specimen tape 190, wherein the feeder reel 175 is rotatably coupled to the reel-to-reel frame 182. A take-up reel 177 is also adapted to receive the specimen tape 190 across the reel-to-reel frame 182, and the reel-to-reel frame 182 is configured to integrate with the knife stage adapter 550 and connect to an ultramicrotome 150 that transfers cut samples onto the specimen support tape 190. The specimen tape is not limited to any one material but can include, without limitation, a graphene coated tape, as described above, and the tape may also be a conductive tape. These tapes hold resin based microscopic sections of cells and tissues thereon and are sufficiently pliable to wind around hubs of the feeder reel 175 and the take up reel 177 at a desirable tension between the reels. In one embodiment, the reel-to-reel frame 182 positions the feeder reel 175 and the take-up reel 177 near the ultramicrotome with the reels being exposed. It is notable that the reel-to-reel frame 182 holds the feeder reel 175 and the take-up reel 177 such that the reels are modular and separable components that connect to the reel-to-reel frame 182. In this way, the reels can be transferred from specimen collection operations of an ultramicrotome 150 to other machinery such as numerous kinds of microscopes and imaging apparatuses.

The feeder reel 175 and the take-up reel 177 may be, but are not limited to, machined aluminum wheels having respective hubs 173A, 173B for wrapping the specimen tape 190. The respective hubs 173A, 173B have a calibrated circumference, produced by precise machining often of aluminum, adapted to maintain a speed and a tension of the specimen tape 190 extending between the feeder reel 175 and the take-up reel 177. The aluminum material for the reels 175, 177, the hubs 173A, 173B, and the wheels on the hubs that secure the tape, is useful for its properties allowing precise control of conductivity and magnetic shielding.

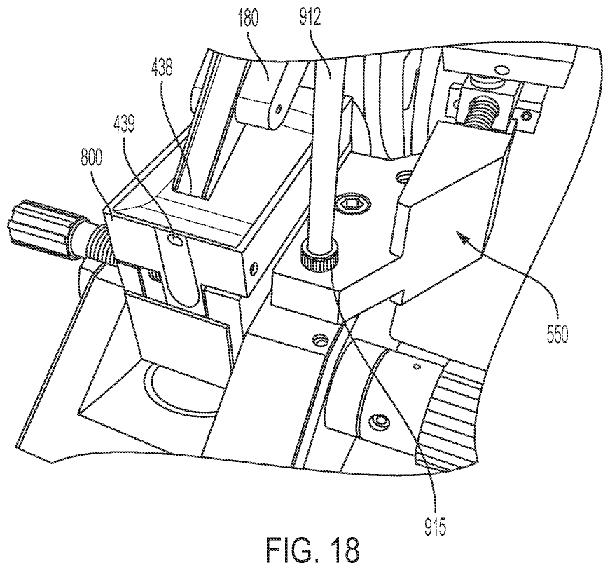

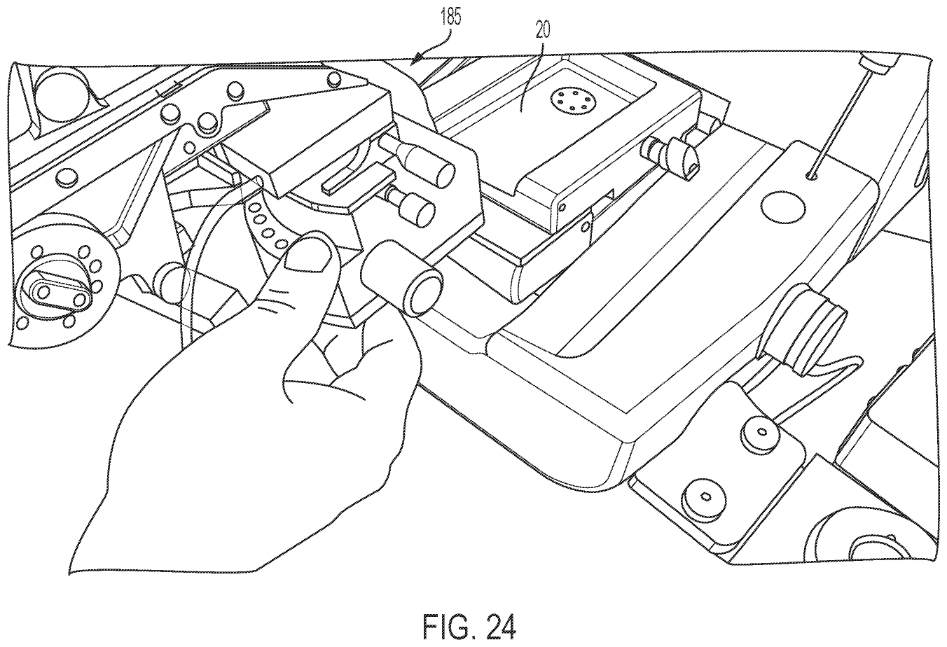

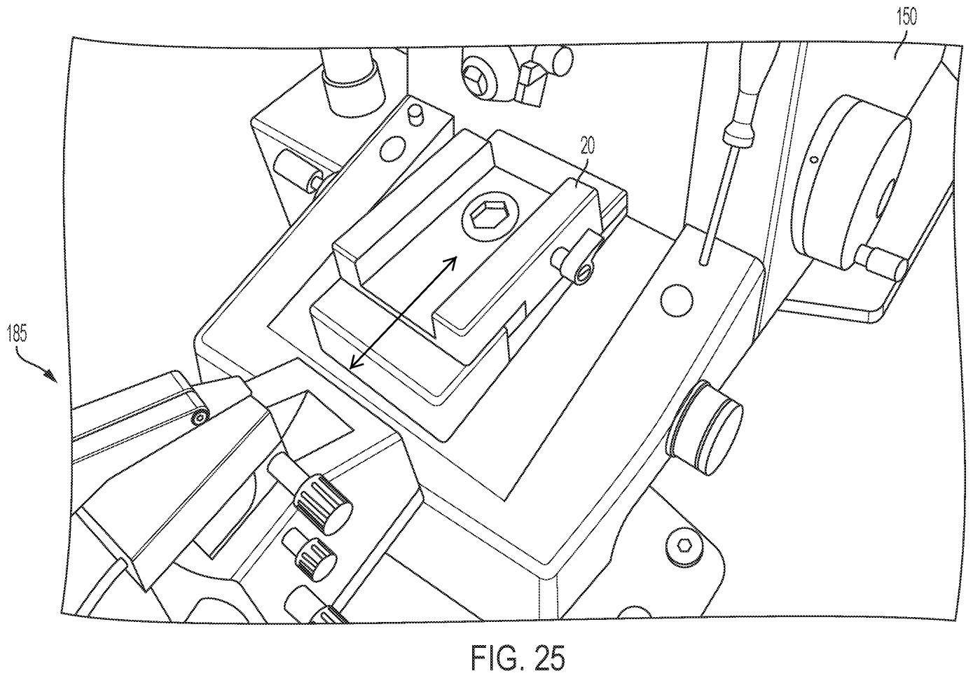

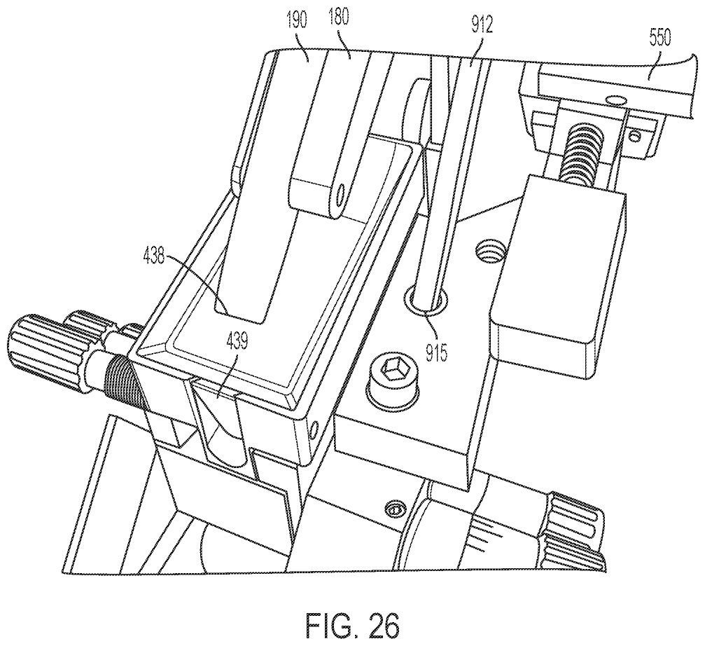

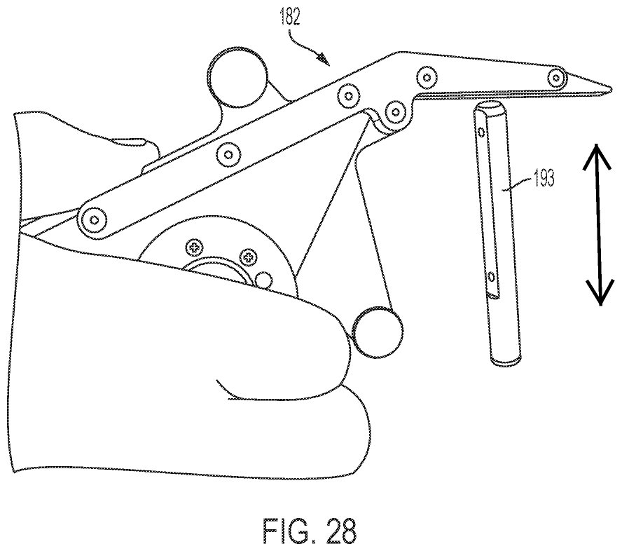

The feeder reel 175 and the take-up reel 177 include aluminum compositions that are sufficient for withstanding temperatures inside of in-situ scanning electron microscopes that are equipped to use a reel-to-reel imaging system. Such temperatures in the environment of a scanning electron microscope may rise to the range of 1400 degrees Celsius to 1500 degrees Celsius. As noted above and illustrated in FIGS. 18, 24, and 25, the reel-to-reel frame 182 is detachable from the knife stage adapter 550 without removing the feeder reel 175 or the take-up reel 177 or the specimen tape 190. The reel-to-reel frame 182 is adapted to re-attach to additional imaging systems, and the additional imaging systems are selected from but not limited to secondary electron imaging systems, backscatter electron imaging systems, and scanning transmission electron microscopy imaging systems. The additional imaging systems are further selected from quantitative measurement imaging systems comprising EDS and EELS systems. FIGS. 4, 26 illustrate that the modular arrangement of both the knife stage adapter 550 and the various central specimen holders (i.e., a reel-to-reel frame, a trigger holder, and vise) can be connected and removed numerous combinations to form a plurality of assemblies. In FIGS. 4, 26, one non-limiting assembly shows the reel-to-reel frame connected to the knife stage adapter and that assembly is removably attached to the knife stage as discussed herein. As shown in FIG. 28, components of this disclosure may be stored on stand 193 for future use.

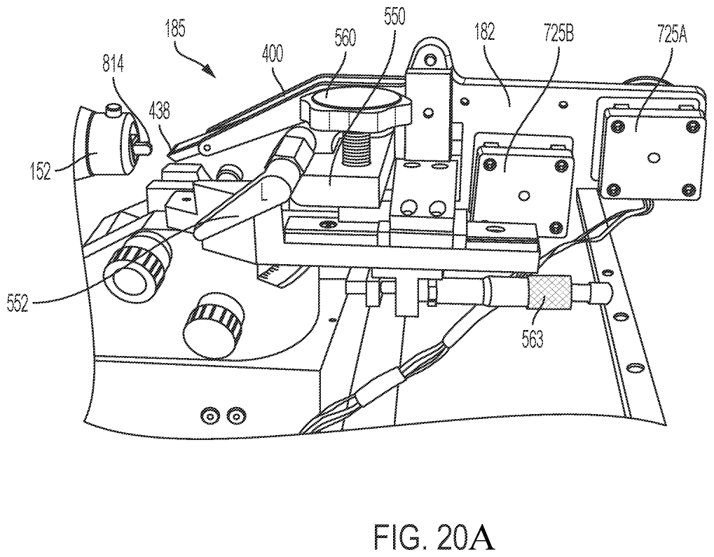

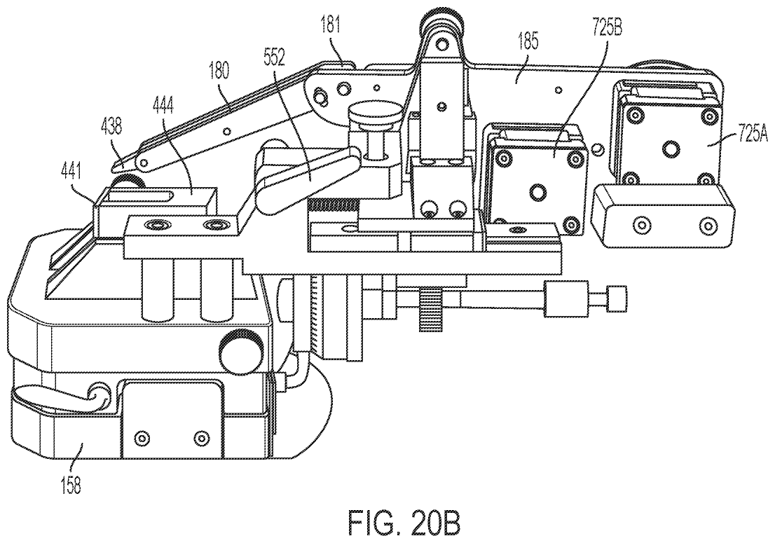

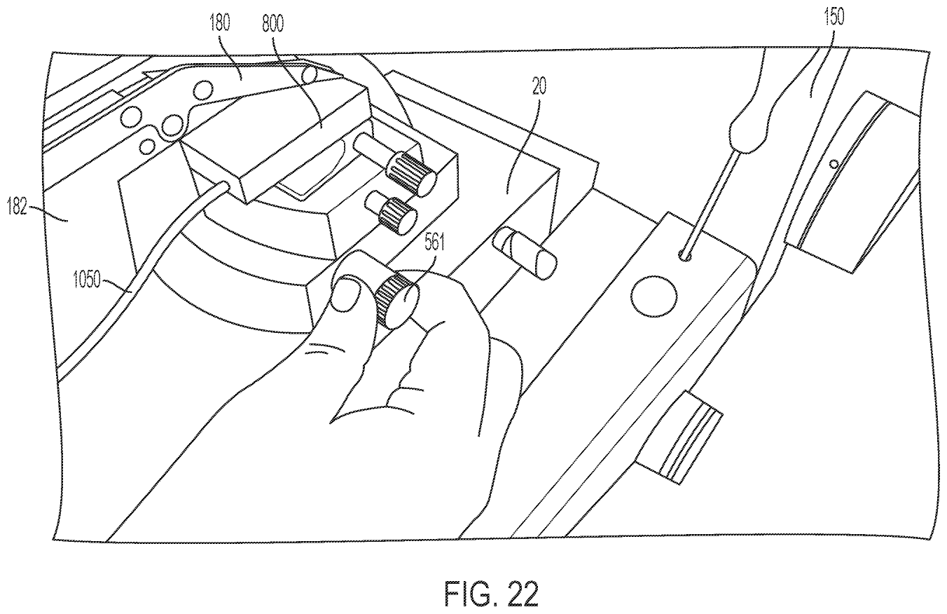

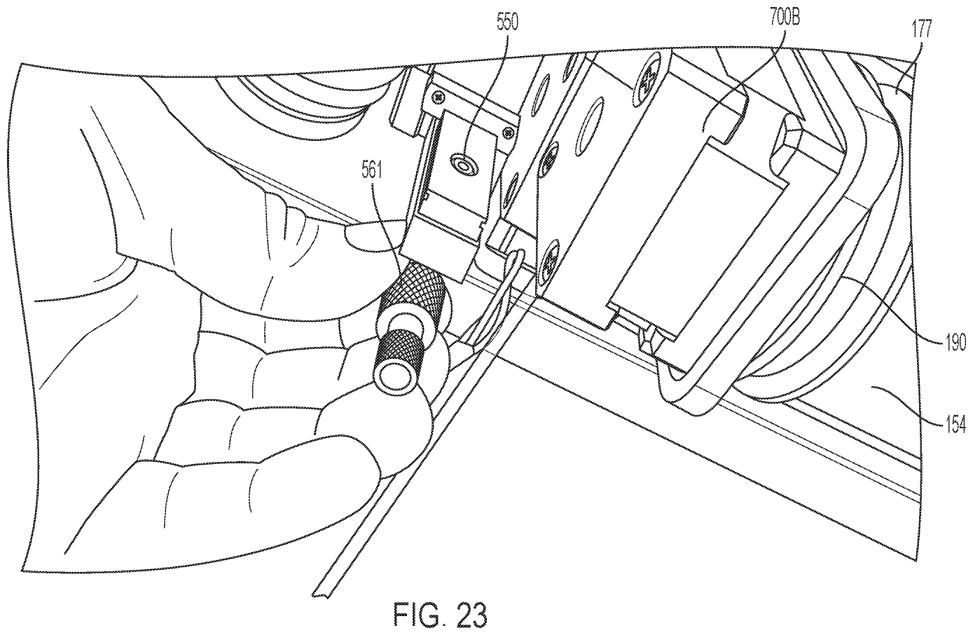

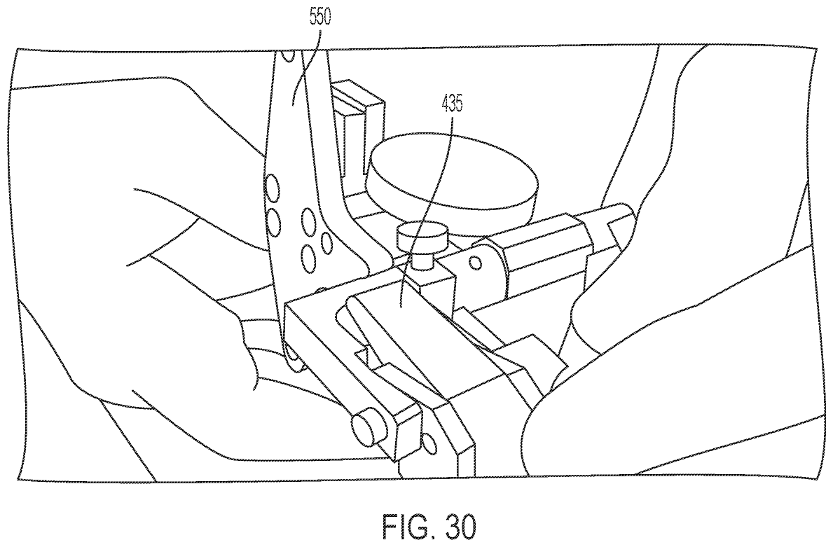

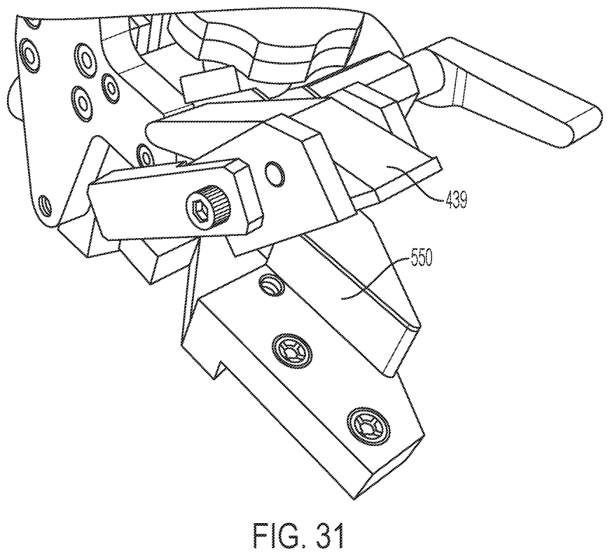

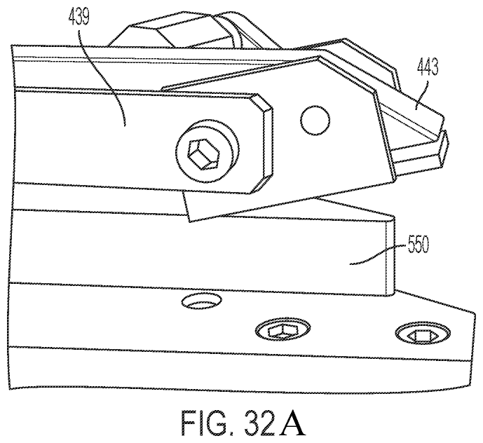

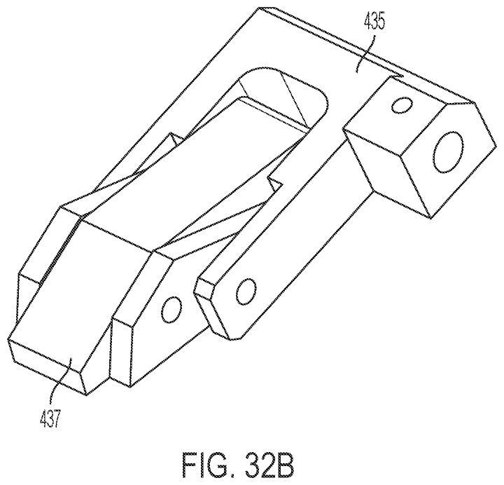

This disclosure presents several different kinds of central specimen holders 182, 300, 435 that can be positioned relative to an ultramicrotome knife stage 158 and specimen cantilever arm 152 to receive sliced specimens on a number of different slides, or substrates. The modular, separable components of the knife stage adapter 550 and the numerous kinds of central specimen holders 182, 300, 435 allow for complete versatility in specimen collection and specimen analysis with other kinds of equipment. FIG. 22 illustrates additional versatility by including numerous mechanisms 561 for adjusting a position of the knife stage adapter 550, a reel-to-reel frame 182, a trigger holder 300, a clip holder or vise 435 (FIGS. 30, 31, 32A, 32B), and many other kinds of central specimen holders. As shown in FIGS. 20-23, adjustment mechanisms may be utilized with macro position adjustment knobs 560 and micro position adjustment knobs 561 that can assist in moving the apparatuses in the X, Y, and Z Cartesian coordinates of FIG. 2B. These positional adjustments may also be implemented by many different electronic and software driven machines as described herein.

The versatility of these operations is shown in a system for preparing cut samples with an ultramicrotome 150. In FIGS. 3-21, the system is shown with a modular reel-to-reel assembly 185 connected to the knife stage adapter 550 and the ultramicrotome 150. In at least one embodiment, the system includes a reel-to-reel frame 182 and a knife stage adapter 550, wherein the knife stage adapter 185 is adapted to connect the modular reel-to-reel assembly 185 to the ultramicrotome 150. The modular reel-to-reel assembly 185 may be described as incorporating the reel-to-reel frame 182 along with components and combinations of components including, but not limited to, a feeder reel 175 connected to a length of a specimen tape 190, wherein the feeder reel 175 is rotatably coupled to the reel-to-reel frame 182. A take-up reel 177 is connected to the reel-to-reel frame 182 and receives the specimen support tape 190 across the reel-to-reel frame 182. In one non-limiting embodiment, the reels are removable from the reel-to-reel frame with or without disassembling the knife stage 158, the knife stage adapter 550, or the specimen tape 190. The reels 175, 177 may be attached to a separate plate that connects by various fasteners to the reel-to-reel frame 182.

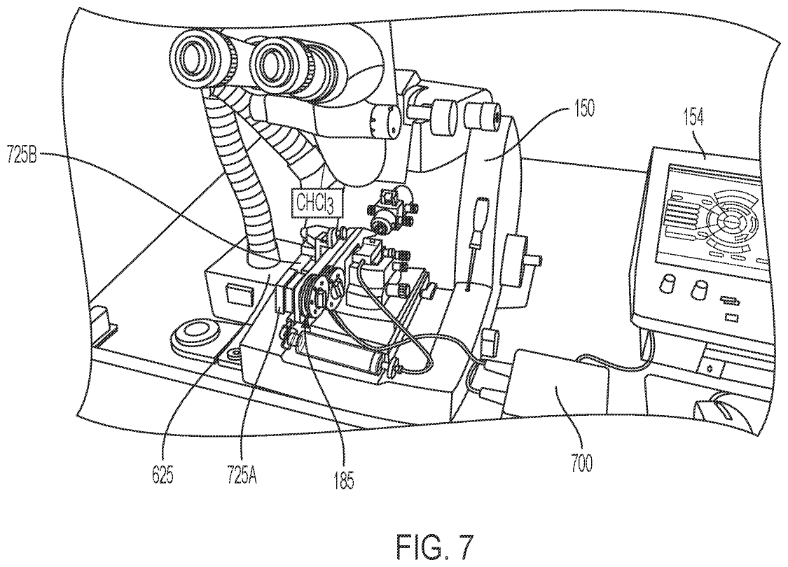

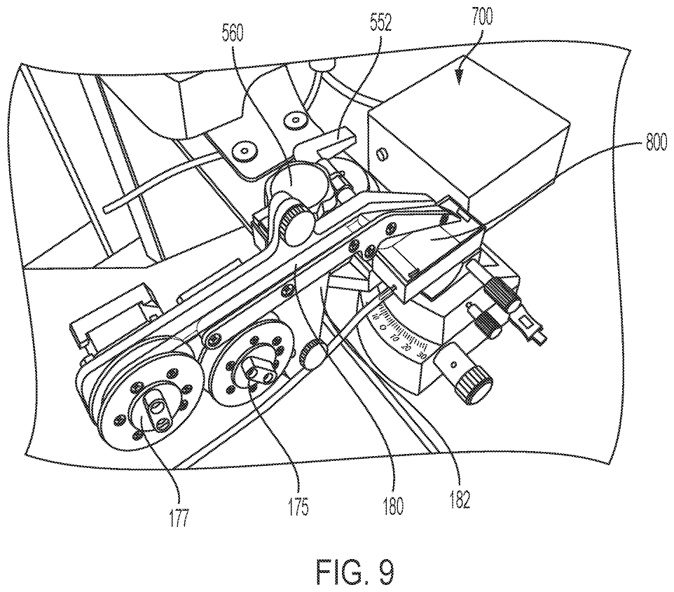

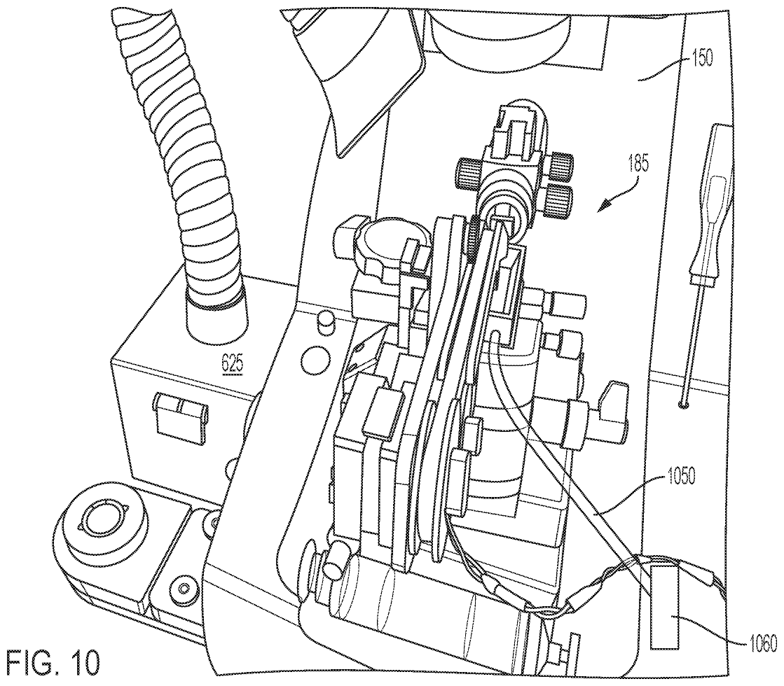

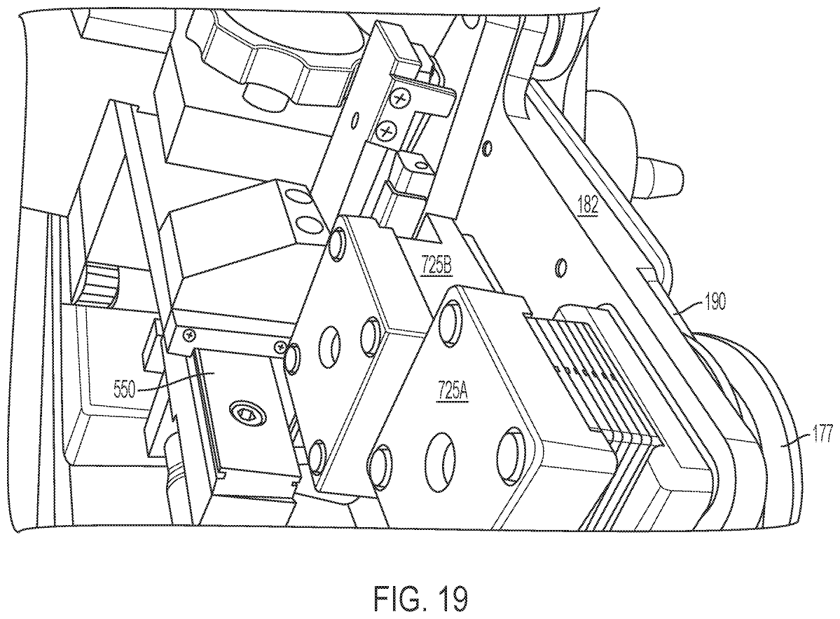

As shown in FIGS. 10, 19 and others, the reel-to-reel frame 182 connects to or supports, a feeder motor 725B that drives rotation of the feeder reel 175 and a take-up motor 725A that drives rotation of the take-up reel 177. It is important to note that in some embodiments, the reel-to-reel assembly 185 includes only the feeder reel 175 and the take up reel 177 that are separable from the reel-to-reel frame 182. In other embodiments, the system may include a plurality of sample position sensors 1410, 1420 connected to the modular reel-to-reel assembly 185 and/or the ultramicrotome 150 that sends data to the electronic controller 700 (FIGS. 7, 9) regarding where the ultramicrotome specimen cantilever arm 152 is located in its arcuate path. Other embodiments utilize a single sensor on the platform of the ultramicrotome to detect where the ultramicrotome specimen cantilever arm 152 is located on its path. In this way, the electronic controller described below is updated with the position of the sample on the ultramicrotome specimen cantilever arm 152 and knows when the specimen tape 190 must advance to maintain continuity. The electronics and programming of the electronic controller 700 are discussed in more detail below. The positions of the sensors 1410, 1420 are not limited to any one installation and can be relocated for the use at hand. With data from the sensors 1410, 1420, at least one electronic control unit 700 is equipped for controlling respective speeds of the feeder motor 725B and the take-up motor 725A, wherein the electronic control unit 700 adjusts the respective speeds according to a sample position signal received from the plurality of sample position sensors 1410, 1420. As shown in the figures, the ultramicrotome specimen cantilever arm connects to an ultramicrotome chuck that has the nib 814 for holding a specimen block to be cut.

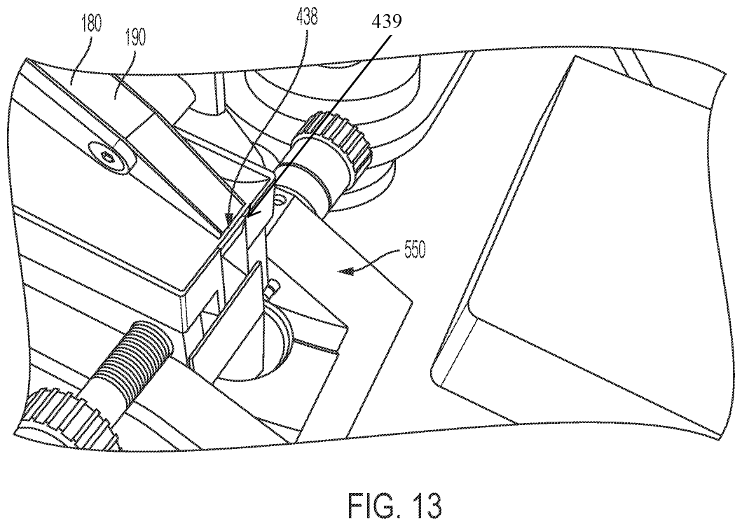

The system of FIGS. 3-21 further illustrates an ultramicrotome specimen cantilever arm 152 holding a specimen block in engagement with a knife edge 439 connected to a knife boat 800, wherein the sample position sensors include at least the first sensor 1410 on the knife boat and a second sensor 1420 on the ultramicrotome specimen cantilever arm 152, but these positions are entirely optional. The specimen tape 190 is positioned to receive samples on the specimen tape 190 from the knife edge 439 attached to the knife boat 800 connected to a knife carrier 20 connected to the ultramicrotome 150. The specimen tape traverses the tape guide 180 across a nose or snorkel 438 as shown in FIG. 20 (i.e., a portion of the tape guide that is submerged into water in the knife boat 800 filled from pump line 1050 (FIG. 10) to pump 1060 (FIG. 10). In one embodiment, the tape guide 180 may include a joint 181 that allows for different heights of the snorkel or nose end 438. The tape guide, therefore, may have multiple degrees of freedom in the x, y, and z directions for the best placement of the tape in receiving a specimen slice. As shown in FIGS. 13-15 and FIG. 17, the nose end 438 of the tape guide is moveable by the various position controllers of the knife stage, the knife stage adapter, and the reel-to-reel frame. The nose end 438 is positioned relative to a knife edge 439 to receive a cut specimen onto a tape 190.

As noted above in regard to FIGS. 7 and 9, operation of the system may be coordinated by an electronic controller 700 that may further include a graphical user interface 154 connected to the electronic control unit 700 and configured to receive data entry for programming the electronic control unit. The data entry may include programming optional parameters to maintain variables such as speed selections for the feeder motor 725B and the take-up motor 725A, which in one embodiment may be a stepper motor. The electronic controller 700 may be characterized as having general purpose inputs and outputs that are connected to appropriate processors, computerized memory, and hardware that is appropriate for customized machine logical operations. In one non-limiting example, the electronic controller receives data from a system of sensors, including a first cantilever arm position sensor and a second cantilever arm position sensor, either of which may be located on the cantilever arm and/or the body of the ultramicrotome. This data, along with speed data for the motors can be used for numerous control systems programmed into the electronic controller. For example, in one embodiment, by using the speed of the motors and the rotation speed of the reels, along with dimensions of the tape and linear speed of the tape, the electronic controller is adapted to track position coordinates of each cut resin section that is located on the tape. In this way, the electronic controller includes a computer registry or database that allows for tracking where a specimen is located along the tape and which sections of the tape are empty. This is useful information when the tape with specimens thereon are “played back” for microscopy purposes.

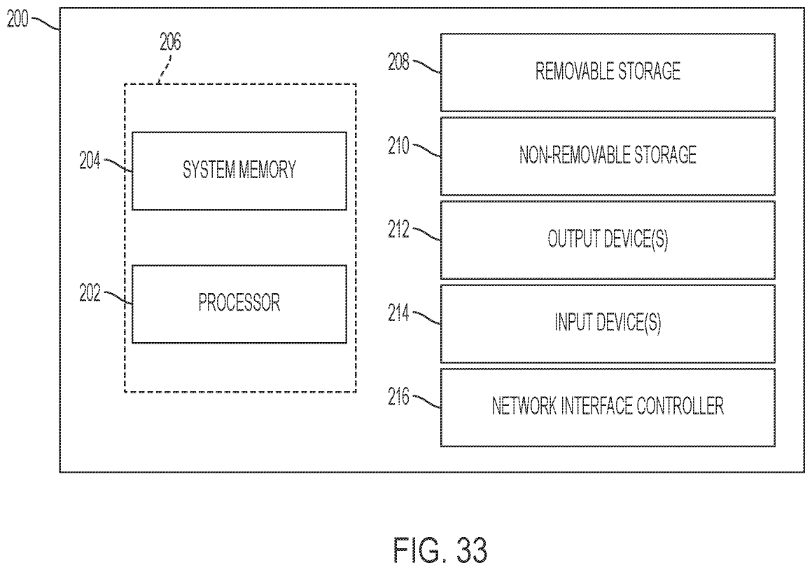

This disclosure accounts for multiple, non-limiting versions of the firmware for the control environment, illustrated in FIGS. 7 and 33 at least. Each version consists of several modules for different tasks. In one embodiment, software for the electronic controller 700 includes a tape control module. Its task is to maintain a constant speed of the tape 190 by taking the two spool diameters (i.e., the diameters of hubs 173A, 173B) and spool revolutions per unit time into consideration and using this information to control the two respective step motor speeds, connected to the spools. Another feature of the module is the access of the hardware settings of the motor controller on the board. The communication module uses a transmission protocol to communicate with a user interface software via the USB interface of the hardware.

One non-limiting version of the firmware is considered for the knife stage 550 with an additional slicer arm monitor module. This module monitors the periodical movement of a slicer arm with the help of a sensor. The information of the slicer arm speed controls the tape speed, which is important to maintain a constant distance between the sliced samples.

The second version of the firmware may be used for the tape coating hardware of companion disclosures. Besides the tape control module, another module for controlling a third step motor, is included. This motor module handles the coating of the tape by turning at a constant speed. The tape heater module is measuring the temperature of a heater block by an RDT sensor. An implemented PID control maintains a set temperature of the heating block, whose output controls an electric heating element attached to the heating block.

Using various embodiments of this disclosure to operate a scanning electron microscopy procedure is the third version of the firmware. In addition, for the tape control module, an analog joystick is attached to the controller. The joystick can control the tape speed, tape direction as well as sample position during manual mode. This is important to center the sample for the microscope.

In non-limiting example embodiments of a controller 700, there are three operations. All three operations have the tape control in common, which can have two different modes. If the source spool motor has no encoder attached, the user has to set the initial revolutions of the sink—spool and source—spool manually on the interface. With an encoder, only the revolution of the sink—spool has to be set. The controller will calculate the revolution of the source-spool automatically. For the knife stage operations, the knife-stage operation can be run with two different modes, depending if the slicer monitor is activated. If the knife-stage runs without the slicer monitor, the user can set the tape speed and the tape direction. With the activated slicer monitor, instead of tape speed and direction the user can set sample distance. In this mode, the tape direction always goes from source-spool to sink-spool. The tape speed is calculated by the sample distance and the monitored speed of the slicer arm.

When the tape is played back for use with scanning electron microscopy (SEM) operation, the user first has to center the first sample manually with the joystick. On the interface then the user has to set sample distance. This information has to be taken from the interface of the knife-stage controller. Another important setting is the scan time of the sample, which pauses the tape during sample scan.

In a coating operation of companion embodiments to this disclosure, there are three settings. The first setting is the speed of the coating motor. This determine in combination with the tape speed, how much material will be coated on the tape. The other two settings are heating temperature and heating exposure time. The heating exposure time will determine the speed of the tape. The tape direction is fixed in this mode and can only go from source-spool to sink-spool.

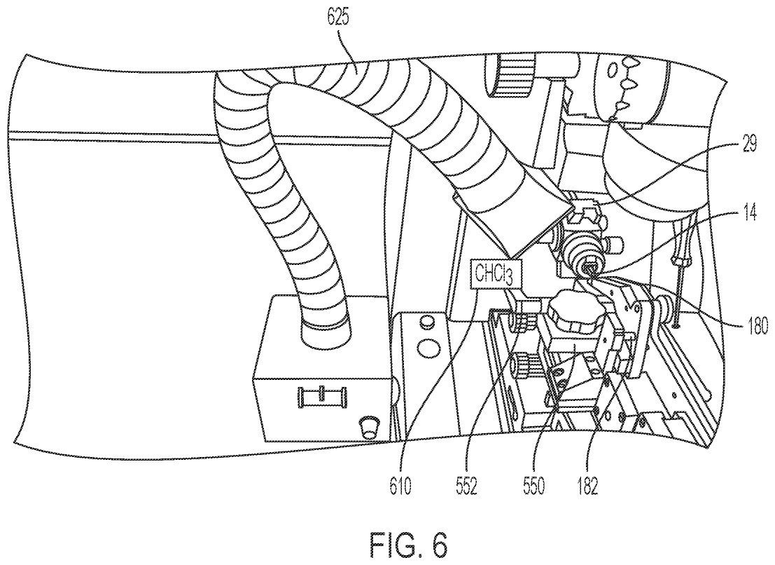

The figures, such as but not limited to FIGS. 6, 7, and 8, further illustrate that the system may include specimen unfolding additives to the environment. When the sample is sliced from a sample block attached to a nib 814 on the ultramicrotome arm 152, its initial contact with the knife edge 439 moves the sample slice into water of the knife boat 800, and that process tends to fold the sample or crimple the surface of the sample. Systems of this disclosure utilize additives to the environment of the knife boat 800 to unfold the sample. In one non-limiting embodiment, the unfolding agent is chloroform 614 as shown in the figures emitted from a mister assembly that directs the chloroform toward the sliced sample to unfold it. As shown in FIG. 6, the system also includes an exhaust arrangement 625 to remove excess gaseous additives such as chloroform from the work area.

As noted above, the knife stage adapter 550 is also accessible for attaching other central specimen holders to the ultramicrotome 150 for sample collection. In this embodiment, a sample substrate holder for receiving a cut sample from an ultramicrotome 150 includes a clip type holder, also called a vise 435, for specimen collection in preparation for array tomography. In one non-limiting embodiment, a knife stage adapter 550 is configured for removable attachment to a knife stage 158 on an ultramicrotome 150, wherein the knife stage adapter 550 defines X, Y, and Z axes relative to the ultramicrotome. As shown in FIGS. 30-32, a clip, or vise, 435 is attached to the knife stage adapter 550, wherein the clip or vise 435 is configured to hold a graphene substrate in a position to receive the cut sample thereon. A lever arm 552 is configured for arcuate movement about the knife stage adapter 550 to position a nose end 437 of the clip 435 at selectable points along the Z axis and adjacent a sample block on the ultramicrotome 150.

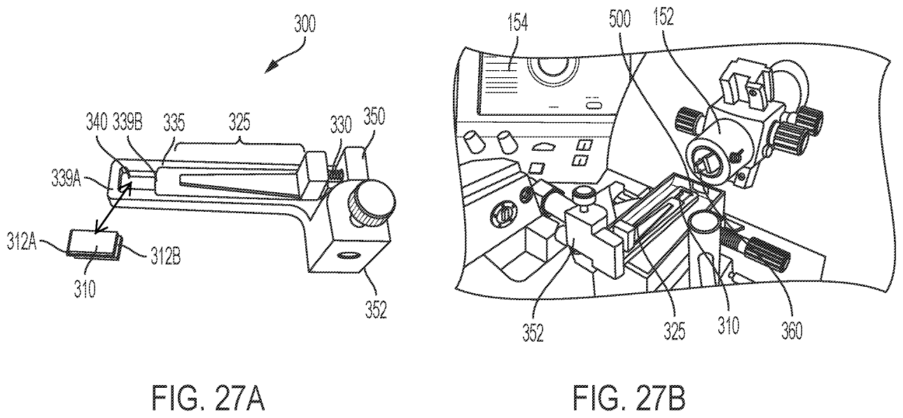

A sample substrate holder may also encompass a trigger holder as illustrated in FIGS. 27A, 28B for array tomography and possibly for additional use with scanning electron microscopes. The trigger holder body 300 is illustrated extensively in FIGS. 27A and 27B for use with an ultramicrotome. As illustrated in FIGS. 27A, 27B, the substrate holder body 300 defines a passageway with a first opening 340 at one end of the holder body 300 and a second opening 335 extending from the first opening 340 toward a second end of the holder body. A trigger 325 fits within the second opening 335, wherein the trigger 325 is actuated by a spring 330 connected to the trigger 325 and the holder body 300. A removable surface block 310 is configured to fit within the first opening 340 of the holder body 300, and the removable surface block 310 is held in place by the trigger 325 biased by the spring 330. In operation, the knife stage adapter 550 positions the removable surface block 310 proximate the ultramicrotome 150. A sample can be collected onto a graphene sample substrate that is positioned across the surface block 310 and held in place between sides 312A, 312B of the surface block 310 connected to respective sections 339A, 339B of the holder body 330 and the trigger 325.

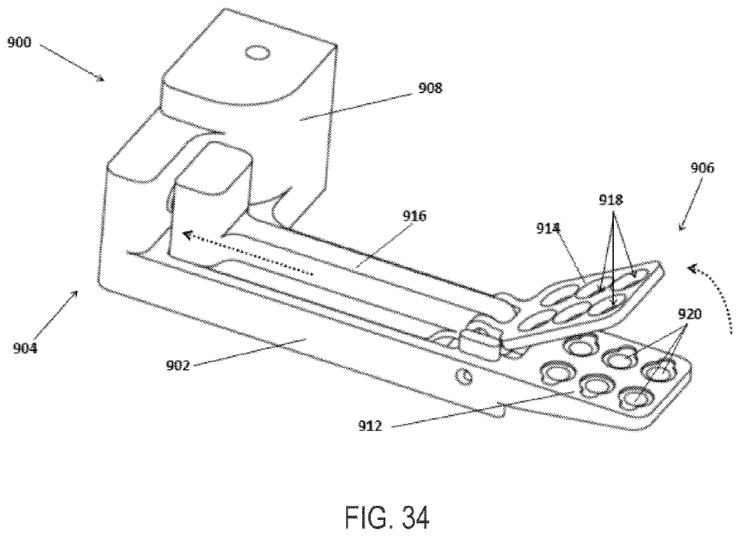

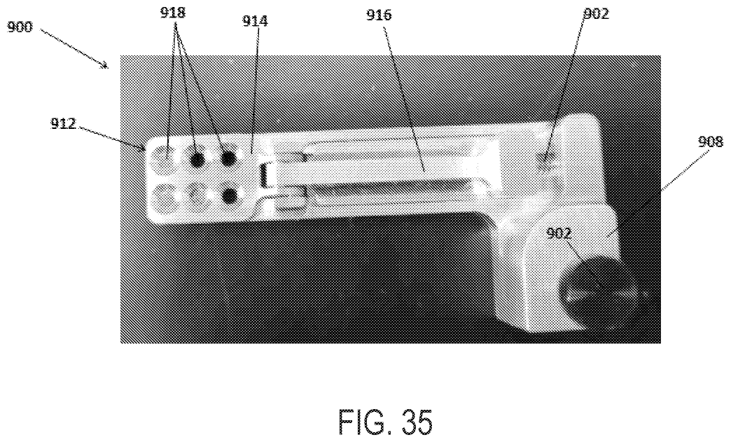

As illustrated in FIGS. 34 and 35, also provided herein are multigrid holders 900 that can be used to facilitate the user's transfer and placement of sectioned samples at target regions on one or more sample substrates (e.g., grids) during sectioning operations performed on the ultramicrotome. In some aspects, the multigrid holders 900 can comprise a body portion 902 extending from a proximal region 904 to a distal region 906. A mounting bracket 908 can be coupled to the body portion 902. A distal mounting plate 912 can be disposed beneath an engageable substrate cover 914. The multigrid holder 900 can further comprise a lever 916 extending from the proximal region 904 towards and operatively coupled to the engageable substrate cover 914, such that actuation of lever 916 (as illustrated by a dotted arrow) shifts the engageable substrate cover 914 from a first position (shown in FIG. 35) where the engageable substrate cover 914 is in intimate contact with the distal mounting plate 912 to a second position (shown in FIG. 34) where the engageable substrate cover 914 is raised above the distal mounting plate 912 (as illustrated by a dotted arrow). The engageable substrate cover 914 can comprise one or more apertures (918) that define regions of the distal mounting plate 912 that are exposed when the engageable substrate cover 914 is in the first position.

Mounting bracket 908 can be adapted to engage and couple to a knife stage adapter described herein. In certain aspects, the mounting bracket 908 can be adapted to engage and couple to the lever arm 552 of a knife stage adapter described herein (for example, by fastening to and/or engaging with rod 582). The mounting bracket 908 can further comprise a fastener 910, such as a set screw or bolt, adapted to secure the mounting bracket (and by extension the multigrid holder) to the knife stage adapter.

In some embodiments, advancement of lever 916 towards the proximal region 904 of the body portion shifts the engageable substrate cover 914 from the first position (shown in FIG. 35) to the second position (shown in FIG. 34). In certain embodiments, a spring 922 is engaged with the lever 916 to provide resistance to proximal advancement of the lever 916 and/or to ensure that the engageable substrate cover 914 remains in the first position absent an applied force to the lever.

In some aspects, the multigrid holders can further comprise one or more sample substrates disposed on the distal mounting plate 912 and secured beneath the engageable substrate cover 914. In these cases, the one or more apertures 918 can define regions of the sample substrates that are exposed for sample deposition.

In some aspects, the distal mounting plate can comprise one or more recesses 920 formed within the distal mounting plate 912. These recesses can each be sized to receive a sample substrate. In certain aspects, when the engageable substrate cover 914 is in the first position, the one or more recesses 920 are registered with the one or more apertures 918 in the engageable substrate cover 914, such that a sample substrate present in the one or more recesses 920 are exposed for sample deposition.

In some aspects, the one or more recesses 920 are sized to accept an electron microscopy grid. For example, in certain aspects, the one or more recesses 920 are about 3.05 mm in diameter. The one or more apertures 918 can be slightly smaller than 3.05 mm in diameter so as to secure the electron microscopy grids beneath the engageable substrate cover 914 when the engageable substrate cover 914 is in the first position. However, the one or more apertures 918 can still be large enough to permit sectioned samples to be placed on the sample substrate through the apertures.

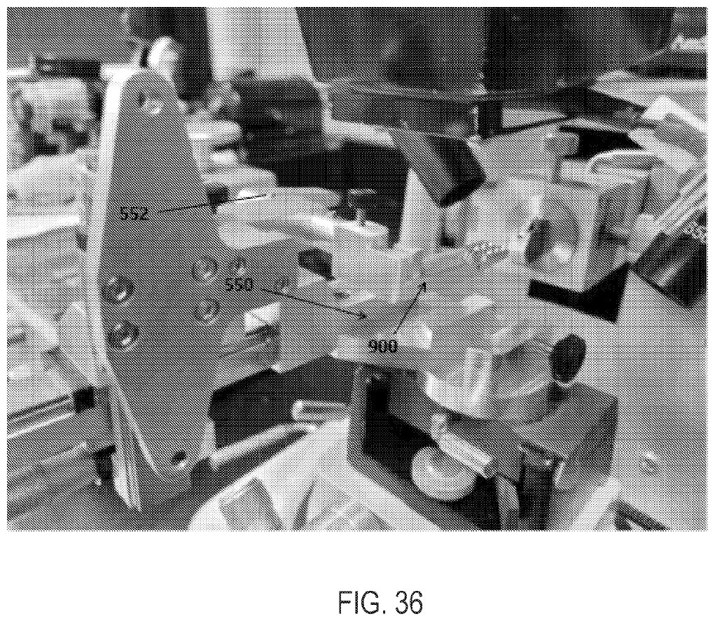

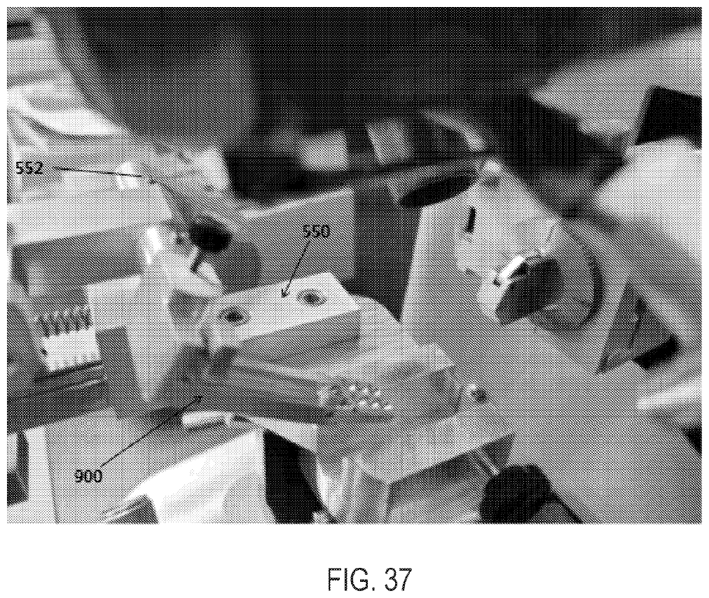

FIGS. 36 and 37 illustrate an example multigrid holder attached to a knife stage adapter. As shown in FIG. 37, the mounted multigrid holder can be oriented using the lever arm of the knife stage adaptor so as to position the distal region of the multigrid holder in proximity to the knife boat of the ultramicrotome (not shown). In some embodiments, the distal region of the multigrid holder can be positioned in contact with a fluid present in the knife boat. This can allow the user to easily transfer sectioned samples from the knife blade to target regions on one or more sample substrates during sectioning operations performed on the ultramicrotome.

Any one of the above noted central sample substrate holders, including the reel-to-reel embodiments, the clip embodiments, or the trigger embodiments can be used to perform methods of sample collection. Along these lines, a method of transferring samples from an ultramicrotome to a specimen tape includes positioning a sample block onto a nib 814 (FIG. 16) of the ultramicrotome 150; connecting a length of the specimen tape 190 between a feeder reel 175 and a take-up reel 177 connected to a reel-to-reel frame 182; advancing the specimen tape 190 from the feeder reel 175 to the take-up reel 177; positioning the specimen tape 190 between the sample block and a knife stage 158 connected to the ultramicrotome 150, wherein a knife edge 439 mounted on the knife stage 158 receives a portion of the sample block against a knife edge 439 to slice at least one sample of the sample block; and receiving the sample on the specimen support tape 190 and advancing the specimen support tape. The method continues by advancing the specimen support tape 190 with respective stepper motors 1410, 1420 that drive rotation of the feeder reel and the take-up reel. Advancing the specimen support tape 190 may occur in iterative steps or on a continuously driven tape. 26. The method of any one of claims 23-25, further comprising programming an electronic control unit 700 to advance the specimen support tape 190.

The system and apparatuses of this disclosure are configured to provide a maximum flexibility for a method of transferring samples from an ultramicrotome to a specimen substrate. As noted above, the ultramicrotome may be used with a number of different kinds of central specimen holders, including but not limited to a reel-to-reel system, a trigger holder system, and a clip mechanism. Each of these different embodiments enable a method of positioning a sample block onto a nib 814 of the ultramicrotome 150; connecting a specimen substrate to a central specimen holder 185, 300, 435; positioning the specimen substrate between the sample block and a knife stage adapter 550 connected to the ultramicrotome 150, wherein the knife stage adapter 158 receives a portion of the sample block against a knife edge 439 to slice at least one sample from the sample block; and receiving the sample on the sample substrate.

As noted above, the ultramicrotome 150 has a knife stage 158 that may operate with a knife stage adapter 550 to receive the central specimen holder in adjustable positions and connecting the central specimen holder to an electronic control unit configured to update respective adjustable positions of the central specimen holder. The respective adjustable positions lie in a Cartesian X, Y, and Z plane defined by the knife stage adapter 550, and the electronic controller 700 is configured to move the central specimen holder in at least one direction in the Cartesian X, Y, Z plane. The method can continue by (i) connecting a reel-to-reel frame 182 with a feeder reel 175 and a take up reel 177 as the central specimen holder, (ii) connecting a clipping apparatus 435 for array tomography as the central specimen holder, or (iii) connecting a triggered holder apparatus 300 for array tomography as the central specimen holder. By placing the electronic controller 700 in data communication with a control computer having a graphical user interface 154 and programming the electronic controller 700 with the control computer, the methods herein may be automated.

Automated methods of this disclosure include a method of transferring a cut sample section of a specimen block attached to an ultramicrotome 150 onto an electron microscopy specimen tape 190 by attaching a feeder reel 175 wrapped with the specimen tape 190 to a reel-to-reel frame 182 aligned with the specimen block on the ultramicrotome 150; placing at least part of the specimen tape 190 on a tape guide 180 across the reel-to-reel frame 182, attaching an end of the specimen support tape 190 to a take-up reel 177; rotating the feeder reel 175 and the take-up reel 177; advancing the specimen tape 190 from the feeder reel 175 to the take-up reel 177 along the tape guide 180 and wrapping the specimen tape 190 around the take-up reel 177; and receiving the cut sample section onto the substrate strip for storage on the take-up reel 177. The automated methods enable receiving a semi thick or thin ultramicrotome cut sample onto the sample tape 190 while simultaneously using respective motors 1410, 1420 to rotate the feeder reel 175 and the take-up reel 177 in a controlled way of advancing the specimen tape 190. Upon completion, the method as disclosed herein optionally includes removing the reel-to-reel frame 182 from the ultramicrotome 150 without disrupting the feeder reel 175, the take up reel 177, or the specimen tape 190.

The automated methods described above are enabled in part by utilizing an electronic controller 700 for implementing tape-based electron microscopy on a sample received onto a sample support tape 190. The electronic controller 700 may move the specimen tape 190 that is advanced from a feeder reel 175 to a take-up reel 177 connected to an ultramicrotome 150. The electronic controller typically includes a computer processor 200 connected to computerized memory storing computer-implemented software implementing programmable, computerized steps of a method. The method includes positioning the specimen support tape 190 between a sample block and a knife stage connected to the ultramicrotome, wherein the knife stage receives a portion of the sample block against a knife edge to slice at least one sample of the sample block; receiving the sample on the specimen support tape 190; and advancing the specimen support tape.

As shown in the figures, the feeder reel 175 and the take up reel 177 are connected to an exposed reel-to-reel frame 182, and the computer implemented software further comprises computer implemented commands to position the exposed reel-to-reel frame in a Cartesian X, Y, Z coordinate system to receive the sample on the specimen support tape. The computer implemented software comprises computer implemented commands to set at least one speed of the respective motors. The speed of the respective motors is coordinated by the electronic controller 700 in conjunction with arcuate motion 21 of the sample block against the knife edge 439 as controlled by the ultramicrotome 150.

The terminology used herein is for the purpose of describing particular implementations only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The implementation was chosen and described in order to best explain the principles of the invention and the practical application, and to enable others of ordinary skill in the art to understand the invention for various implementations with various modifications as are suited to the particular use contemplated.

The figures utilize an exemplary computing environment in which example embodiments and aspects may be implemented. The computing device environment of FIG. 33 is only one example of a suitable computing environment and is not intended to suggest any limitation as to the scope of use or functionality.

Numerous other general purpose or special purpose computing devices environments or configurations may be used. Examples of well-known computing devices, environments, and/or configurations that may be suitable for use include, but are not limited to, personal computers, server computers, handheld or laptop devices, multiprocessor systems, microprocessor-based systems, network personal computers (PCs), minicomputers, mainframe computers, embedded systems, distributed computing environments that include any of the above systems or devices, and the like.

Computer-executable instructions, such as program modules, being executed by a computer may be used. Generally, program modules include routines, programs, objects, components, data structures, etc. that perform particular tasks or implement particular abstract data types. Distributed computing environments may be used where tasks are performed by remote processing devices that are linked through a communications network or other data transmission medium. In a distributed computing environment, program modules and other data may be located in both local and remote computer storage media including memory storage devices.

In its most basic configuration, a computing device typically includes at least one processing unit and memory. Depending on the exact configuration and type of computing device, memory may be volatile (such as random-access memory (RAM)), non-volatile (such as read-only memory (ROM), flash memory, etc.), or some combination of the two.

Computing devices may have additional features/functionality. For example, computing device may include additional storage (removable and/or non-removable) including, but not limited to, magnetic or optical disks or tape. Such additional storage is illustrated in FIG. 2 by removable storage and non-removable storage.

Computing device typically includes a variety of computer readable media. Computer readable media can be any available media that can be accessed by the device and includes both volatile and non-volatile media, removable and non-removable media.

Computer storage media include volatile and non-volatile, and removable and non-removable media implemented in any method or technology for storage of information such as computer readable instructions, data structures, program modules or other data. Memory, removable storage, and non-removable storage are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by computing device. Any such computer storage media may be part of computing device.

Computing device 200 may contain communication connection(s) that allow the device to communicate with other devices. Computing device may also have input device(s) such as a keyboard, mouse, pen, voice input device, touch input device, etc. Output device(s) such as a display, speakers, printer, etc. may also be included. All these devices are well known in the art and need not be discussed at length here.

It should be understood that the various techniques described herein may be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, may take the form of program code (i.e., instructions) embodied in tangible media, such as CD-ROMs, hard drives, or any other machine-readable storage medium where, when the program code is loaded into and executed by a machine, such as a computer, the machine becomes an apparatus for practicing the presently disclosed subject matter.

1. A knife stage adapter comprising:
a base portion adapted to couple with an upper region of a ultramicrotome knife-stage;
an elastomeric bushing disposed between the base portion and the upper region of the ultramicrotome knife-stage, wherein the elastomeric bushing vibrationally isolates the base portion from the ultramicrotome;
a platform region receiving at least one adjustment screw attaching the platform region to the base portion at a plurality of selectable heights;
an adapter edge configured to receive a plurality of specimen substrate holders in a modular connection.

2. A knife stage adapter according to claim 1, wherein a respective specimen substrate holder is a reel-to-reel frame.

3. A knife stage adapter according to claim 1, wherein a respective specimen substrate holder is a coverslip vise.

4. A knife stage adapter according to claim 1, wherein a respective specimen substrate holder is a triggered holding apparatus.

5. A knife stage adapter according to claim 1, wherein a respective specimen substrate comprises a multigrid holder.

6. A knife stage adapter according to any of claims 1-5, further comprising a lever arm configured for arcuate movement relative to the base portion and configured to adjust a position of the specimen substrate holder along the Z-axis.

7. A knife stage adapter according to any of claims 1-6, wherein the elastomeric bushing comprises a rubber bushing.

8. A knife stage adapter according to any of claims 1-7, wherein the base portion is fastened to the upper region of the ultramicrotome knife-stage via one or more set screws or bolts.

9. A multigrid holder comprising
a body portion extending from a proximal region to a distal region;
a mounting bracket coupled to the body portion;
a distal mounting plate disposed beneath an engageable substrate cover; and
a lever extending from the proximal region towards and operatively coupled to the engageable substrate cover, such that actuation of the lever shifts the engageable substrate cover from a first position where the engageable substrate cover is in intimate contact with the distal mounting plate to a second position where the engageable substrate cover is raised above the distal mounting plate;
wherein the engageable substrate cover comprises one or more apertures that define regions of the distal mounting plate that are exposed when the engageable substrate cover is in the first position.

10. The holder of claim 9, wherein the mounting bracket is adapted to engage and couple to the knife stage adapter defined by any of claims 1-8.

11. The holder of claim 10, wherein the mounting bracket is adapted to engage and couple to the lever arm of the knife stage adapter defined by claim 6.

12. The holder of any of claims 9-11, wherein the mounting bracket further comprises a fastener adapted for securing the mounting bracket to the knife stage adapter.

13. The holder of claim 12, wherein the fastener comprises a set screw or bolt.

14. The holder of any of claims 9-13, wherein advancement of the lever towards the proximal region shifts the engageable substrate cover from the first position to the second position.

15. The holder of claim 14, further comprising a spring engaged with the lever to provide resistance to proximal advancement of the lever and/or to ensure that the engageable substrate cover remains in the first position absent an applied force to the lever.

16. The holder of any of claims 9-15, further comprising one or more sample substrates disposed on the distal mounting plate and secured beneath the engageable substrate cover, wherein the one or more apertures define regions of the sample substrates that are exposed for sample deposition.

17. The holder of any of claims 9-16, wherein the distal mounting plate comprises one or more recesses formed within the distal mounting plate, each sized to receive a sample substrate.

18. The holder of claim 17, wherein when the engageable substrate cover is in the first position, the one or more recesses are registered with the one or more apertures in the engageable substrate cover, such that a sample substrate present in the one or more recesses are exposed for sample deposition.

19. The holder of any of claims 17-18, wherein the one or more recesses are sized to accept an electron microscopy grid.

20. The holder of claim 19, wherein the one or more recesses are about 3.05 mm in diameter, and wherein the one or more apertures are smaller than 3.05 mm in diameter so as to secure an electron microscopy grid beneath the engageable substrate cover when the engageable substrate cover is in the first position.
